(19) United States
(12) Patent Application Publication
(10) Pub. No.: US 2026/0123015 A1
(43) Pub. Date: Apr. 30, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chun-Yuan CHEN, HsinChu (TW); Szu-Chien WU, Baoshan Township (TW); Huan-Chieh SU, Tianzhong Township (TW); Kuo-Cheng CHIANG, Zhubei City (TW); Chih-Hao WANG, Baoshan Township (TW)

(21) Appl. No.: 19/065,043

(22) Filed: Feb. 27, 2025

Related U.S. Application Data
(60) Provisional application No. 63/711,345, filed on Oct. 24, 2024.

(51) Int. Cl. H10D 64/62; H10D 30/00; H10D 30/01; H10D 64/01

(52) U.S. Cl. CPC H10D 64/62; H10D 30/019; H10D 30/501; H10D 64/01

(57) ABSTRACT

A metal silicide layer is formed on a source/drain region of a transistor (e.g., a nanostructure transistor and/or another type of transistor) of a semiconductor device prior to formation of a recess in which a source/drain contact is to be formed. This enables the coverage of the metal silicide layer on the surface of the source/drain region to be defined independently of the coverage of the source/drain contact (which is defined by the recess in which the source/drain contact is formed).

### CROSS-REFERENCE TO RELATED APPLICATION

This Patent Application claims priority to U.S. Provisional Patent Application No. 63/711,345, filed on Oct. 24, 2024, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration).

Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example implementation of a dummy gate formation process described herein.

FIG. 3 is a diagrams of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric (ILD) formation process described herein.

FIG. 7 is a diagram of an example implementation of an active region isolation structure formation process described herein.

FIG. 8 is a diagram of an example implementation of a replacement gate (RPG) process described herein.

FIGS. 9A-9D are diagrams of an example implementation of a cut source/drain process described herein.

FIGS. 10A-10F are diagrams of an example implementation of a metal silicide layer formation process described herein.

FIGS. 11A-11C are diagrams of an example implementation of a metal silicide layer formation process described herein.

FIGS. 12A-12C are diagrams of an example implementation of a metal silicide layer formation process described herein.

FIG. 13 is a diagram of an example implementation of a cut metal gate process described herein.

FIGS. 14A-14D are diagrams of an example implementation of a source/drain contact formation process described herein.

FIG. 15 is a diagram of an example implementation of a semiconductor device described herein.

FIG. 16 is a diagram of an example implementation of a semiconductor device described herein.

FIG. 17 is a diagram of an example implementation of a semiconductor device described herein.

FIG. 18 is a flowchart of an example process associated with forming a semiconductor device described herein.

FIG. 19 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanostructure transistors (e.g., nanowire transistors, nanosheet transistors, gate all around (GAA) transistors, multi-bridge channel transistors, nanoribbon transistors, and/or other types of nanostructure transistors) may overcome one or more of the above-described drawbacks of some types of transistors. However, nanostructure transistors face fabrication challenges that can cause performance issues, manufacturing yield issues, and/or device failures.

For example, various parts of a nanostructure transistor may be susceptible to increased resistance as feature sizes are reduced. One such part of a nanostructure transistor that is susceptible to increased resistance is the connection between a source/drain region of the nanostructure transistor and a source/drain contact formed on the source/drain region. As the sizes (e.g., the lateral widths) of the source/drain contacts are reduced, a source/drain contact may not fully cover the entire surface of an associated source/drain region, resulting in a reduced contact surface area between the source/drain region and the associated source/drain contact. A metal silicide layer may be included between the source/drain region and the source/drain contact to achieve a lower contact resistance between the source/drain region and the source/drain contact. However, if the metal silicide layer is formed in a recess defined for the source/drain contact, the metal silicide layer also may not fully cover the entire surface of the source/drain region, limiting the contact resistance reduction provided by the metal silicide layer.

In some implementations described herein, a metal silicide layer is formed on a source/drain region of a transistor (e.g., a nanostructure transistor and/or another type of transistor) of a semiconductor device prior to formation of a recess in which a source/drain contact is to be formed. This enables the coverage of the metal silicide layer on the surface of the source/drain region to be defined independently of the coverage of the source/drain contact (which is defined by the recess in which the source/drain contact is formed).

A cut source/drain region process may be performed to form dielectric walls that define the coverage of the metal silicide layer on the surface of the source/drain region. The metal silicide layer may be formed such that the metal silicide layer substantially covers the entirety of the surface of the source/drain region between the dielectric walls to achieve approximate full coverage of the surface of the source/drain region exposed between the dielectric walls. A metal capping layer may be formed on (and may substantially fully cover) the metal silicide layer. The recess for the source/drain contact may be subsequently formed to expose at least a portion of the metal capping layer so that the source/drain contact is formed in the recess on at least the portion of the metal capping layer. In this way, if the recess is formed over less than an entirety of the surface of the source/drain region, the metal capping layer and the metal silicide layer provide an electrical connection between the source/drain contact and substantially the entire surface of the source/drain region, thereby enabling a low contact resistance to be achieved for the connection between the source/drain contact and the source/drain region. This may also enable improved contact isolation between adjacent source/drain contacts to be achieved while facilitating contact poly pitch (CPP) scaling and achieving low contact resistance for the source/drain contacts.

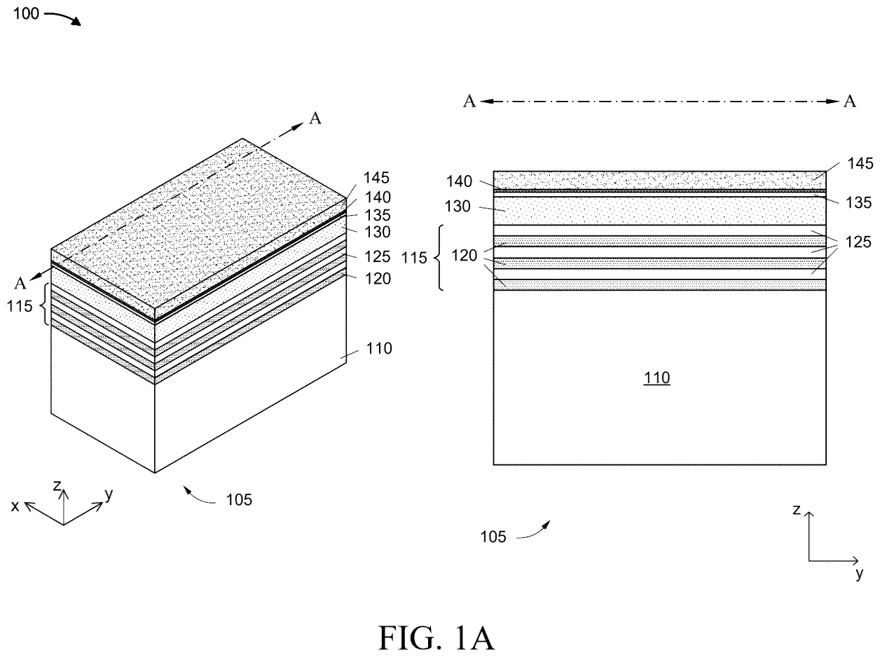

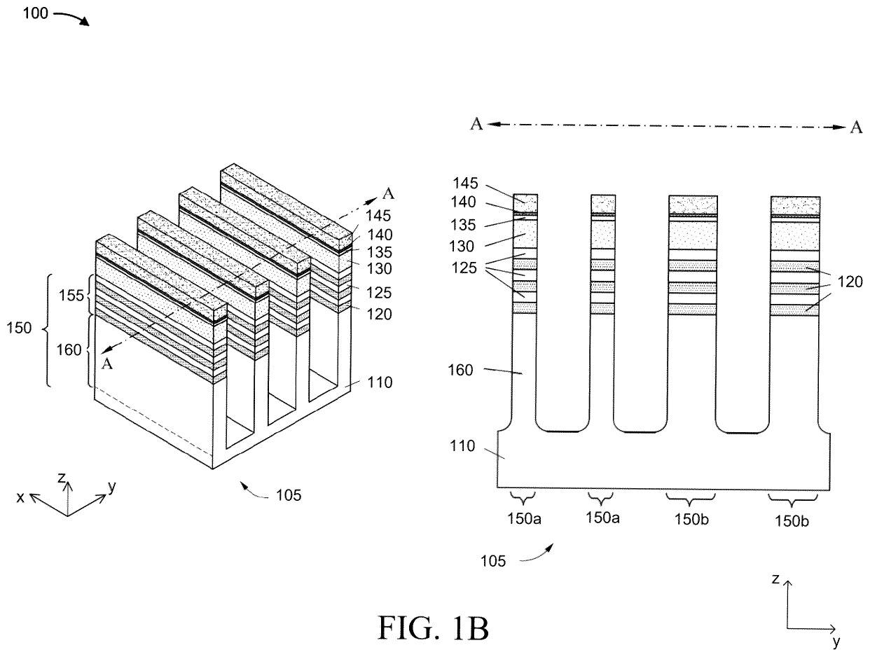

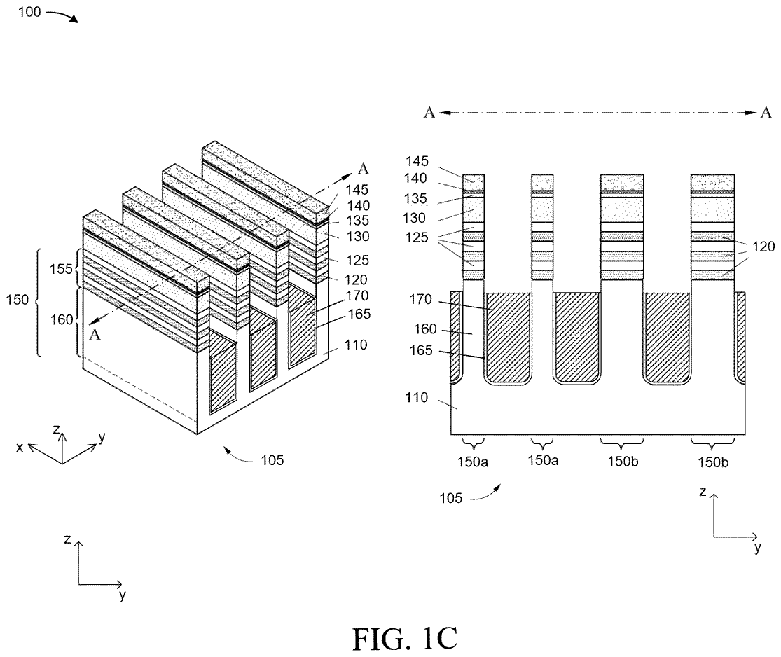

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique.

Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a x-direction in the semiconductor device 105 and may be arranged in an y-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. Alternatively, in some implementations, the liner 165 may be omitted. In implementations in which the liner 165 is included, the liner 165 may include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. The STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

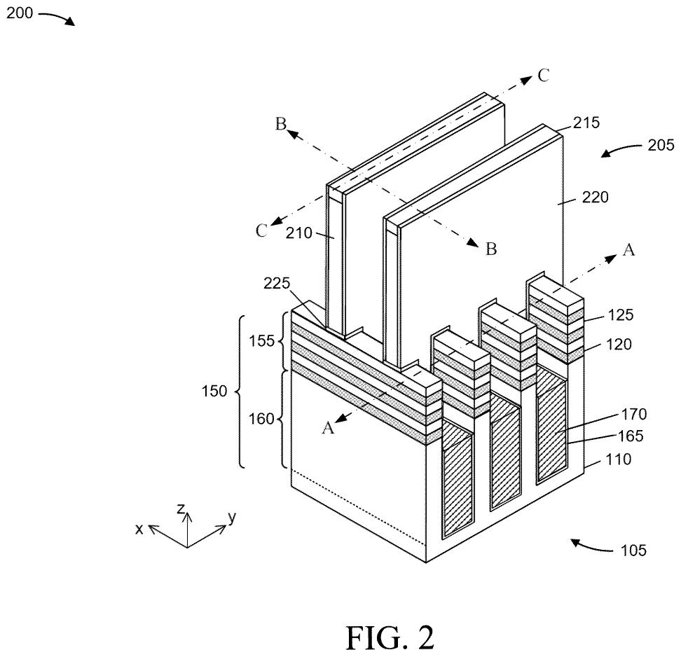

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the y-direction and are arranged in the x-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such as depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

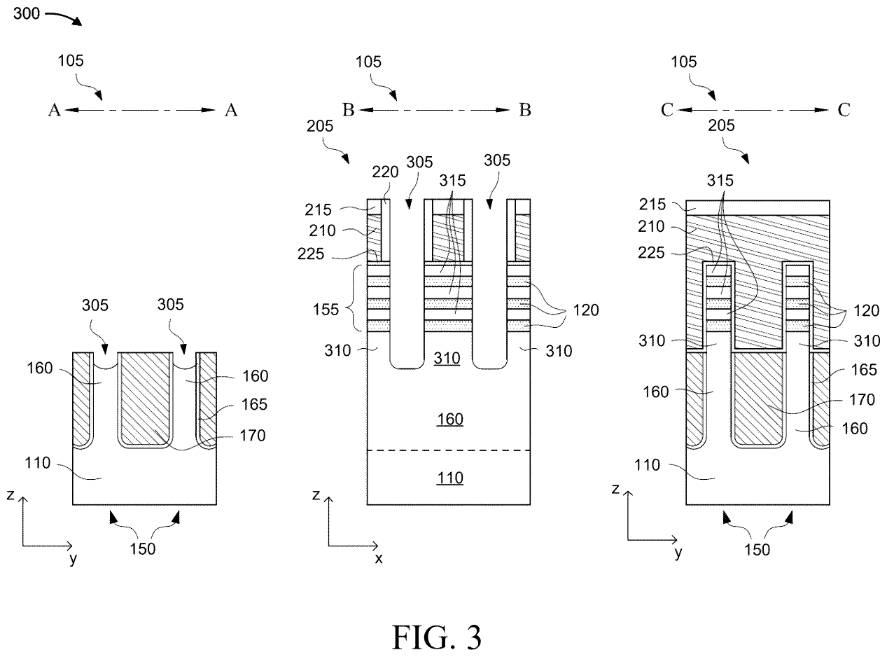

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of protrusions 310 of the fin structure 150. The sidewalls of the portions of each source/drain recess 305 below the layer stack 115 correspond to sidewalls of the protrusions 310. A protrusion 310 (also referred to as a pedestal) refers to a region of the fin portion 160 of the fin structure 150 on which nanostructure channels are defined from the nanostructure channel layers 125. The nanostructure channels 315 extend between adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

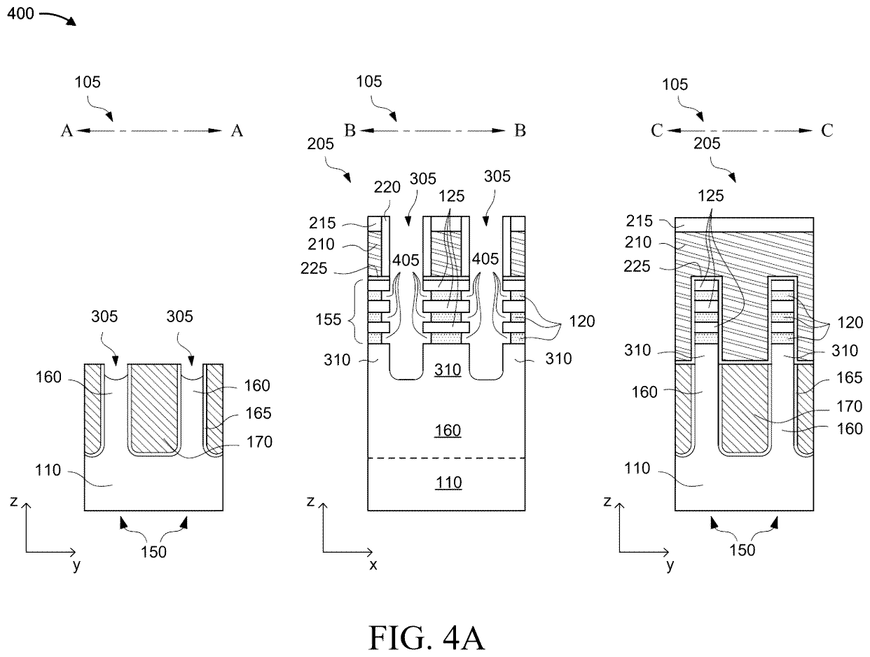

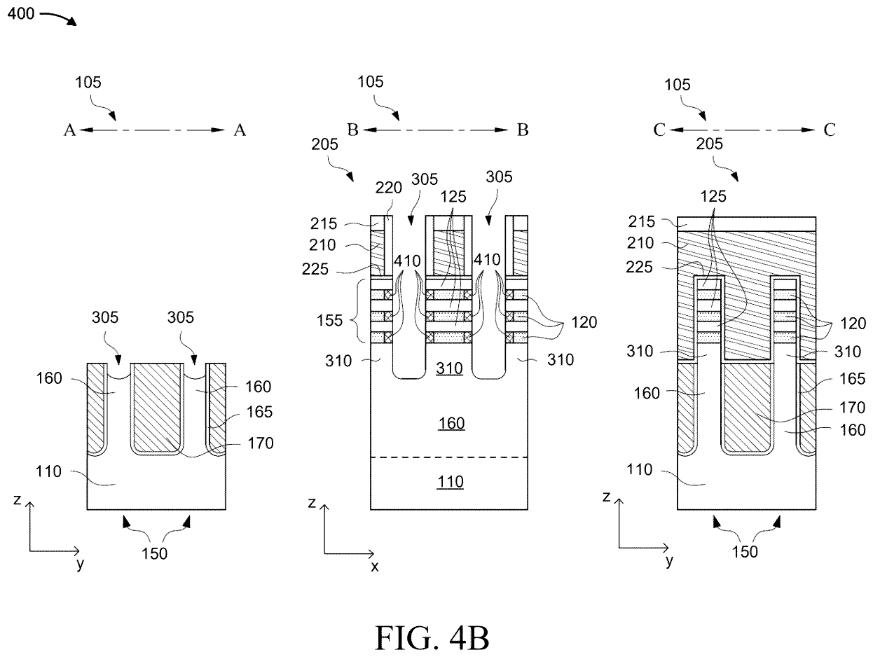

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the y-direction that is approximately parallel to a length of the sacrificial nanostructure layers 120) in an etch operation, thereby forming cavities 405 between the ends of the sacrificial nanostructure layers 120 that are exposed in the source/drain recesses 305. In particular, an etch tool may be use to laterally etch the ends of the sacrificial nanostructure layers 120 under the dummy gate structures 205 through the source/drain recesses 305 to form the cavities 405 between ends of the nanostructure channels 315. The cavities 405 may be formed to an approximately curved shape, an approximately concave shape, an approximately triangular shape, an approximately square shape, or to another shape.

As shown in the cross-sectional plane A-A and in the cross-sectional plane B-B in FIG. 4B, inner spacers (InSP) 410 are formed in the cavities 405 between the ends of vertically adjacent nanostructure channels 315 in the source/drain recesses 305. The inner spacer 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B are provided as an example. Other examples may differ from what is described with regard to FIGS. 4A and 4B.

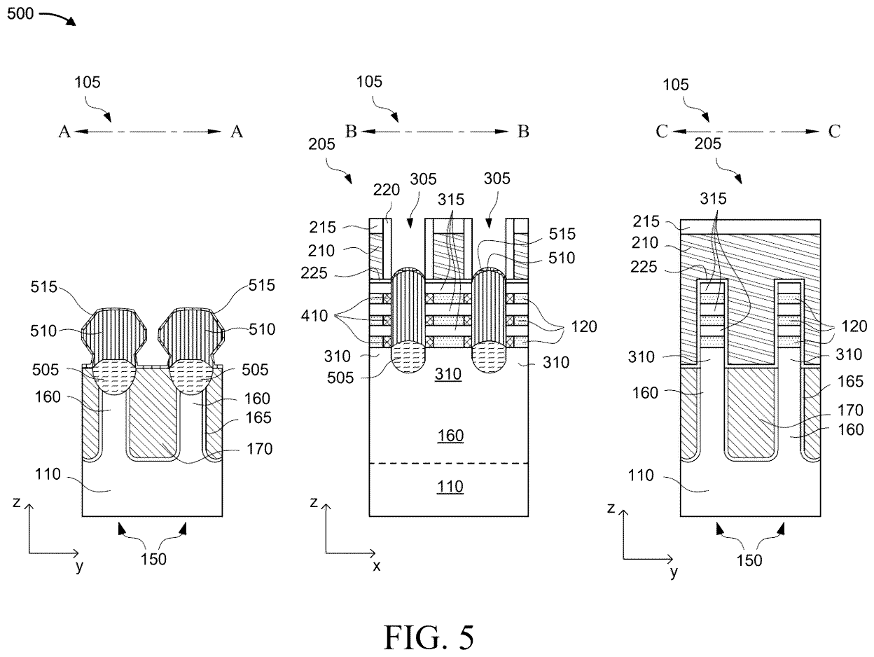

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of the source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (SiB) or another dopant, and/or another material. A buffer region 505 may be included between a source/drain region 510 and the protrusions 310 adjacent to the buffer region 505 to reduce, minimize, and/or prevent dopant migration and/or current leakage from the source/drain region 510 into the adjacent protrusion 310, which might otherwise cause short channel effects in the semiconductor device 105. Accordingly, the buffer region 505 may increase the performance of the semiconductor device 105 and/or increase yield of the semiconductor device 105.

A source/drain region 510 may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain regions 510 in semiconductor processing operations for the semiconductor device 105 prior to contact formation. Moreover, the capping layer 515 may contribute to metal-semiconductor (e.g., silicide) alloy formation.

As indicated above, FIG. 5 is provided as an example. Other examples may differ from what is described with regard to FIG. 5.

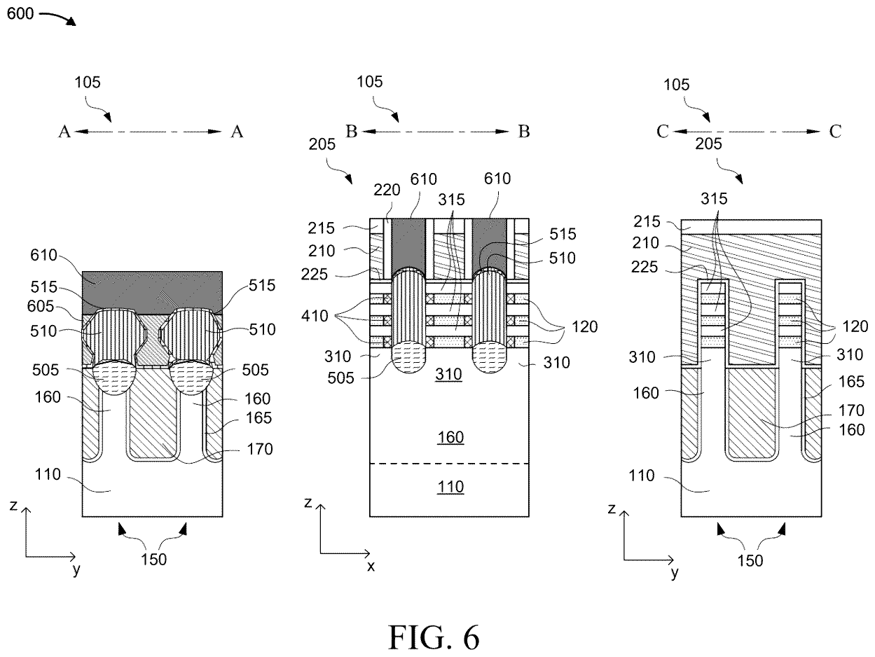

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 600 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer or an ILD zero (ILDO layer)) fills in areas between the dummy gate structures 205. The dielectric layer 605 is formed to reduce the likelihood of and/or prevent damage to the source/drain regions 510 during a replacement gate process to replace the dummy gate structures 205.

In some implementations, a contact etch stop layer (CESL) is conformally deposited (e.g., by a deposition tool) over the source/drain regions 510 prior to formation of the dielectric layer 605. Alternatively, the capping layer 515 may be a CESL. The dielectric layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As further shown in FIG. 6, in some implementations, a dielectric layer 610 may be formed over and/or on the dielectric layer 605. Alternatively, the dielectric layer 610 may be omitted. The dielectric layer 610 may be a dielectric layer that is formed above the ILDO layer, and may include one or more dielectric materials such as silicon nitride (SiₓN_{y}), silicon carbon nitride (SiCN), carbon nitride (CN), silicon oxynitride (SiON), silicon oxycarbide (SiOC), or a combination thereof, among other examples. The dielectric layer 610 may be deposited using a deposition process, such as ALD, CVD, or another deposition technique.

In some implementations, the dielectric layer 610 is deposited such that the dielectric layer 610 is in contact with the tops of the source/drain regions 510. In some implementations, the dielectric layer 610 merges with the capping layer 515 on the source/drain regions 510.

As indicated above, FIG. 6 is provided as an example. Other examples may differ from what is described with regard to FIG. 6.

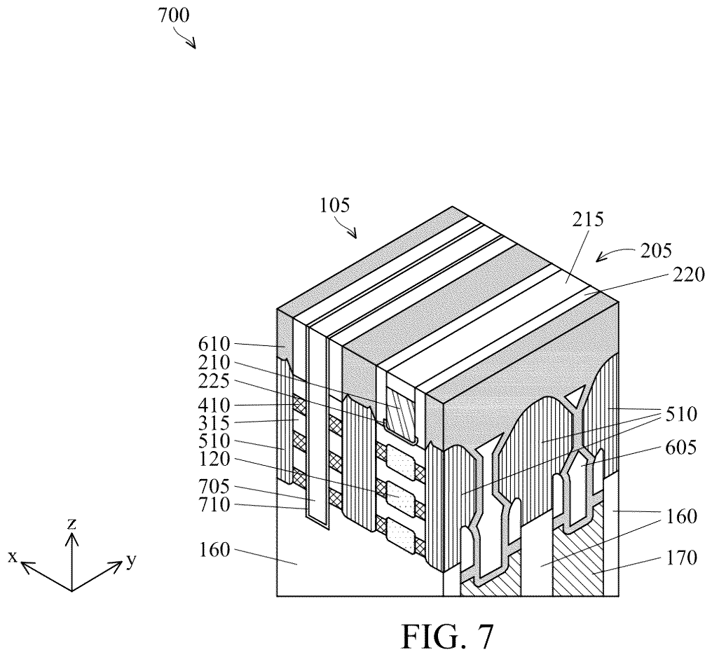

FIG. 7 is a diagram of an example implementation 700 of an active region isolation structure formation process described herein. FIG. 7 is illustrated from a perspective view of the semiconductor device 105. In some implementations, the operations described in connection with the example implementation 700 are performed after the operations described in connection with FIGS. 1A-6.

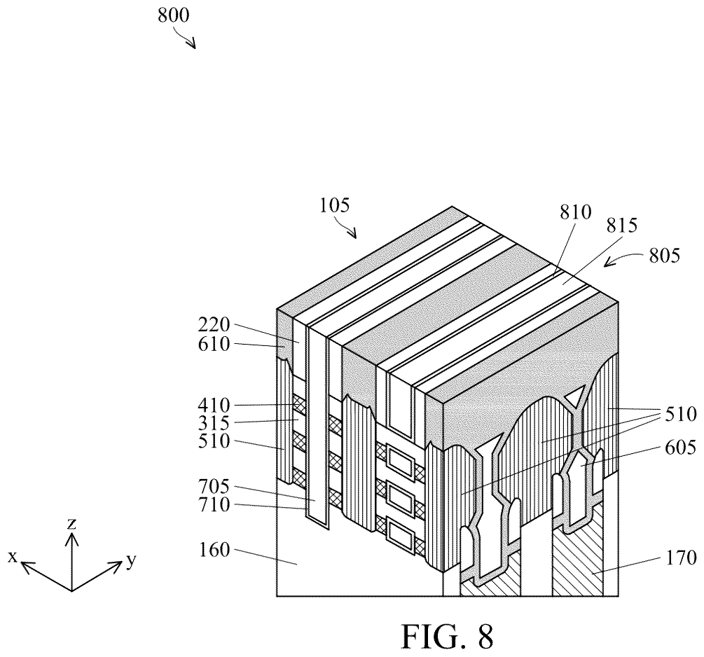

The example implementation 700 includes an example of forming an active region isolation structure (e.g., a cut poly on oxide diffusion edge (CPODE) structure) in the semiconductor device 105 prior to the replacement gate process (which is described in connection with FIG. 8) to replace the dummy gate structures 205 with replacement gate structures (e.g., metal gate structures) of the semiconductor device 105. Therefore, the example implementation 700 may be referred to as a front end of line (FEOL) CPODE process. The active region isolation structure may be formed along a dummy gate structure 205 to create a region of electrical isolation that extends across one or more stacks of nanostructure channels 315 under the dummy gate structure 205.

To form the active region isolation structure, a pattern may be formed in the dielectric layer 610 over a dummy gate structure 205 and an underlying vertical stack of sacrificial nanostructure layers 120 and nanostructure channels 315. The pattern may be used to etch the dummy gate structure 205 and the vertical stack of sacrificial nanostructure layers 120 and nanostructure channels 315, and into an underlying fin portion 160, to form an active region isolation recess (e.g., a CPODE recess). In some implementations, a plurality of vertical stacks of sacrificial nanostructure layers 120 and nanostructure channels 315 under the dummy gate structure 205 may be removed to form the active region isolation recess (and thus, the active region isolation structure) such that the active region isolation recess (and thus, the active region isolation structure) is formed across a plurality of fin portions 160 in the y-direction.

In some implementations, a pattern in a photoresist layer is used to etch the dielectric layer 610 to form the pattern. In these implementations, a deposition tool may be used to form the photoresist layer on the dielectric layer 610 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 610 based on the pattern to transfer the pattern to the dielectric layer 610. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

In some implementations, the dummy gate structure 205, the sacrificial nanostructure layers 120, and nanostructure channels 315 may be removed in a plurality of etch operations to form the active region isolation recess. For example, a first etch operation may be performed to etch and remove the dummy gate structure 205. The first etch operation may stop on the top of the vertical stack of sacrificial nanostructure layers 120 and nanostructure channels 315. A second etch operation may be performed to etch and remove the vertical stack of sacrificial nanostructure layers 120 and nanostructure channels 315. The second etch operation may extend into the underlying fin portions 160. Additionally and/or alternatively, the second etch operation may be non-selective in that the STI regions 170 between the fin portions 160 in the y-direction may also be removed.

As shown in FIG. 7, an active region isolation structure 705 may be formed (e.g., in the active region isolation recess) such that the active region isolation structure 705 extends across (and into) a plurality of fin portions 160 in the y-direction. In some implementations, a dielectric liner 710 may be formed on the sidewalls and on the bottom surface of the active region isolation recess. The dielectric liner 710 may include a dielectric material such as a silicon oxide (SiOₓ such as SiO2), a silicon nitride (SiₓN_{y} such as a Si₃N₄), a silicon oxynitride (SiON), fluoride-doped silicate glass (FSG), a high-k dielectric material, and/or another suitable dielectric material. A deposition tool may be used to deposit the dielectric liner 710 using a PVD technique, an ALD technique, a CVD technique, an oxidation technique, and/or another suitable deposition technique.

The active region isolation structure 705 may be formed on the dielectric liner 710 in the active region isolation recess. A deposition tool may be used to deposit the active region isolation structure 705 using a PVD technique, an ALD technique, a CVD technique, an oxidation technique, and/or another suitable deposition technique. The active region isolation structure 705 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

The active region isolation recess may be over-filled with the material of the active region isolation structure 705 to ensure that the active region isolation recess is fully filled with the material of the active region isolation structure 705 and to minimize the formation of gaps or voids in the active region isolation structure 705. Accordingly, a planarization operation may be performed to planarize the semiconductor device 105 after the active region isolation recess is filled in with the active region isolation structure 705. A planarization tool may be used to perform a CMP operation and/or another type of planarization operation such that the top of the active region isolation structure 705 and the top of the dielectric layer 610 are approximately co-planar.

As indicated above, FIG. 7 is provided as an example. Other examples may differ from what is described with regard to FIG. 7.

FIG. 8 is a diagram of an example implementation 800 of a replacement gate (RPG) process described herein. FIG. 8 is illustrated from a perspective view of the semiconductor device 105. The example implementation 800 includes an example of a replacement gate process for replacing the dummy gate structures 205 with high-k/metal gate structures (e.g., the replacement gate structures) for the nanostructure transistors of the semiconductor device 105. In some implementations, the operations described in connection with the example implementation 800 are performed after the operations described in connection with FIGS. 1A-7.

The replacement gate process may include a dummy gate removal operation. The dummy gate removal operation includes removing the dummy gate structures 205 from the semiconductor device 105. The removal of the dummy gate structures 205 leaves behind openings (or recesses) between the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial nanostructure layers 120 (e.g., the silicon germanium layers). This results in openings between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 410. The inner spacers 410 may function as etch stop layers in the etch operation to protect the source/drain regions 510 from being etched.

As shown in FIG. 8, the replacement gate operation includes forming gate structures (e.g., replacement gate structures) 805 in the openings between the source/drain regions 510 and between the inner spacers 410. In particular, the gate structures 805 fill the areas between and around the nanostructure channels 315 that were previously occupied by the sacrificial nanostructure layers 120 such that the gate structures 805 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 805 may also fill in the spaces that were previously occupied by the dummy gate structures 205. Portions of a gate structure 805 are formed in between pairs of nanostructure channels 315 in an alternating vertical arrangement. In other words, the semiconductor device 105 includes one or more vertical stacks of alternating nanostructure channels 315 and portions of a gate structure 805, as shown in FIG. 8.

The gate structures 805 may each include a gate dielectric layer 810 and a metal gate electrode 815. A gate dielectric layer 810 may be a conformal layer that is conformally deposited (e.g., by ALD or CVD, among other examples) onto the nanostructure channels 315 and on sidewalls of the inner spacers 410 prior to formation of the gate electrodes 815. In some implementations, a planarization tool may be used to planarize the gate structures 805 after the gate structures are formed.

The gate dielectric layer 810 may include one or more high-k dielectric materials, such as a silicon nitride (SiₓN_{y}), a hafnium oxide (HfOₓ), a lanthanum oxide (LaOₓ), and/or another suitable high-k dielectric material. A gate electrode 815 may include one or more metal materials such as tungsten (W), cobalt (Co), ruthenium (Ru), and/or titanium (Ti), among other examples. Additionally and/or alternatively, the gate structures 805 may each include one or more work function metal layers for tuning the work function of the metal gate electrode 815. The gate structures 805 may each include additional layers such as an interfacial layer, an adhesion layer, and/or a capping layer, among other examples.

As indicated above, FIG. 8 is provided as an example. Other examples may differ from what is described with regard to FIG. 8.

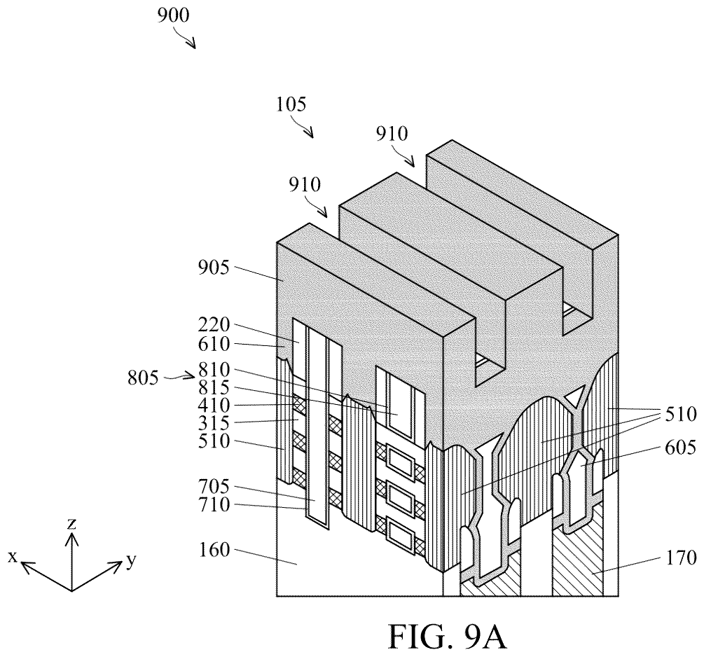

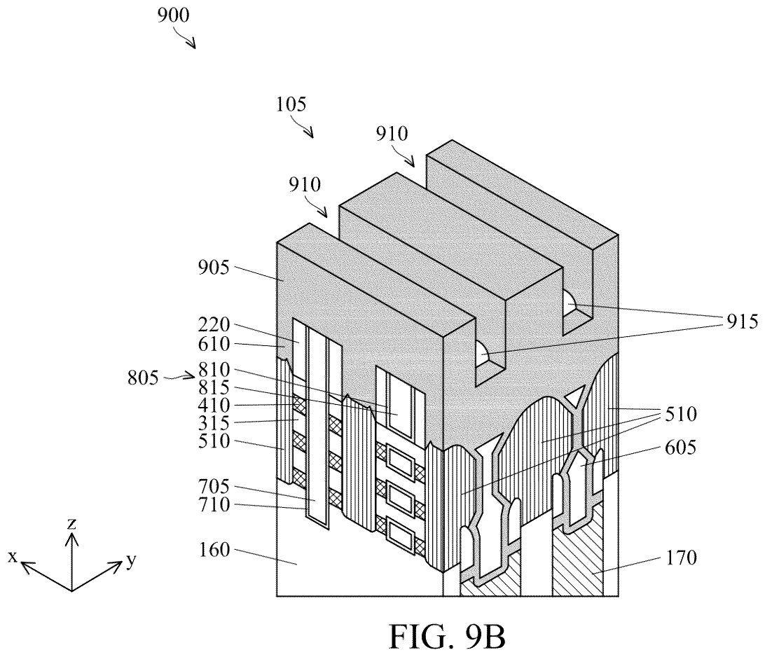

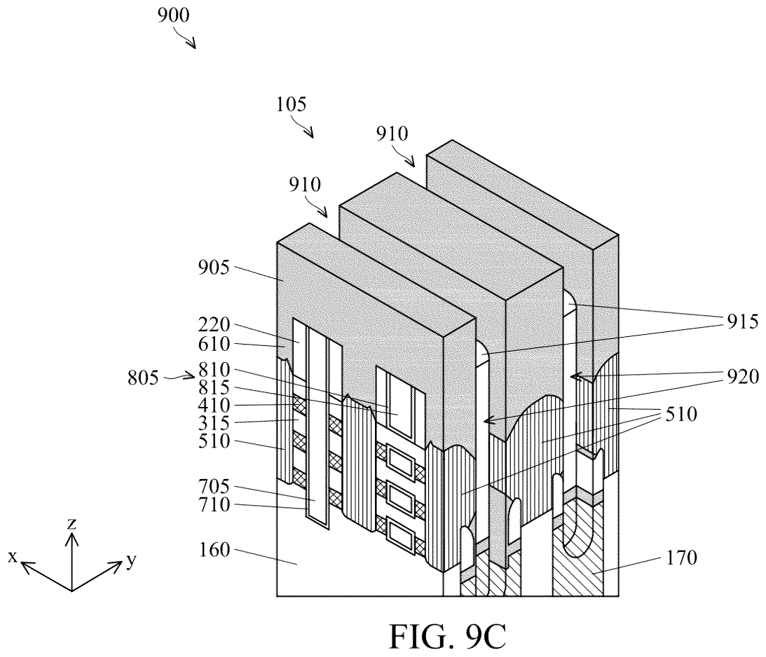

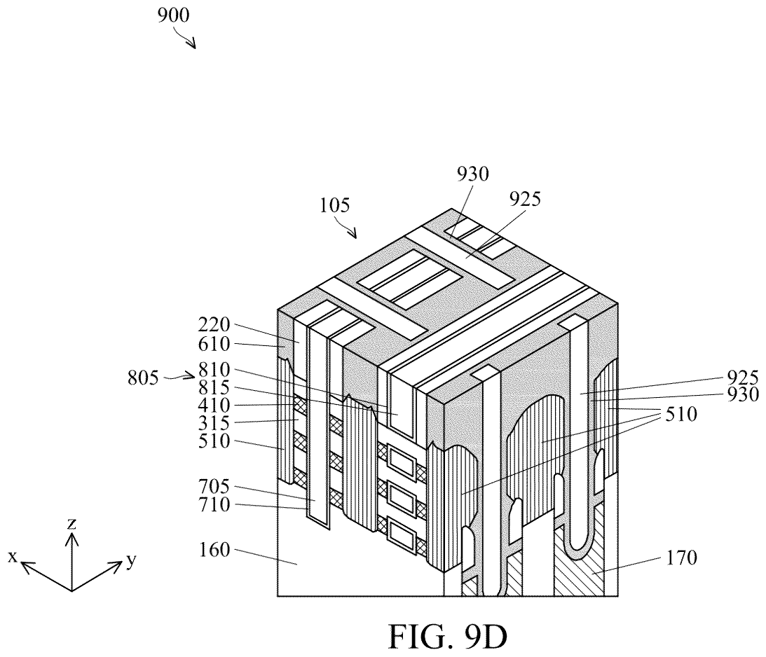

FIGS. 9A-9D are diagrams of an example implementation 900 of a cut source/drain process described herein. FIGS. 9A-9D are illustrated from perspective views of the semiconductor device 105. The cut source/drain process of the example implementation 900 includes an example of forming source/drain isolation structures laterally between adjacent source/drain regions 510 in the y-direction. The source/drain isolation structures provide a well-defined opening in which metal silicide layers may be formed on the tops of the source/drain regions 510 such that the metal silicide layers fully cover the tops of the source/drain regions 510 (which may be difficult to achieve if the metal silicide layers were otherwise formed in a source/drain contact recess defined during a source/drain contact recess process). In some implementations, the operations described in connection with the example implementation 900 are performed after the operations described in connection with FIGS. 1A-8.

As shown in FIG. 9A, a hard mask layer 905 may be formed over and/or on the dielectric layer 610, over and/or on the tops of the active region isolation structures 705, and over and/or on the tops of the gate structures 805. The hard mask layer 905 may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. In some implementations, the hard mask layer 905 and the dielectric layer 610 are formed of the same material. In some implementations, the hard mask layer 905 and the dielectric layer 610 are formed of different materials. A deposition tool may be used to deposit the material of the hard mask layer 905 using a PVD technique, an ALD technique, a CVD technique, an epitaxy technique, an oxidation technique, and/or another suitable deposition technique. In some implementations, a planarization tool may be used to perform a planarization operation (e.g., a CMP operation) to planarize the hard mask layer 905 after the hard mask layer 905 is deposited.

As further shown in FIG. 9A, a pattern 910 may be formed in the hard mask layer 905. The pattern 910 may include openings through the hard mask layer 905. The openings may extend in the x-direction across the dielectric layer 610, across one or more active region isolation structures 705 and/or across one or more gate structures 805. Thus, portions of the dielectric layer 610, portions of one or more active region isolation structures 705 and/or portions of one or more gate structures 805 may be exposed through the openings of the pattern 910 in the hard mask layer 905.

In some implementations, a pattern in a photoresist layer is used to etch the hard mask layer 905 to form the pattern 910. In these implementations, a deposition tool may be used to form the photoresist layer on the hard mask layer 905 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the hard mask layer 905 based on the pattern to form the pattern 910. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 9B, a capping layer 915 may be formed on the tops of the portions of the gate structures 805 exposed through the openings in the pattern 910 in the hard mask layer 905. The capping layer 915 may be included to protect the gate structures 805 from being etched and/or damaged in a subsequent etch operation (e.g., a cut source/drain region etch operation described in connection with FIG. 9C). Alternatively, the capping layer 915 may be omitted. For example if the pattern 910 is not formed on the gate structures 805 and instead is only formed on the region to be cut, the capping layer 915 may be omitted. A deposition tool may be used to deposit the material of the capping layer 915 using a CVD technique, an ALD technique, a PVD technique, and/or another suitable deposition technique.

In some implementations, the capping layer 915 may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material.

In some implementations, the capping layer 915 may include a metal material such as titanium (Ti), tungsten (W), and/or ruthenium (Ru), among other examples. In some implementations, the capping layer 915 may include another material such as tantalum nitride (TaN) and/or titanium nitride (TiN), among other examples.

In some implementations, the capping layer 915 is selectively formed or grown on the tops of the portions of the gate structures 805 exposed through the openings in the pattern 910 in the hard mask layer 905. In other words, the capping layer 915 is selectively formed or grown on the gate structures 805 with little to no growth or deposition of material of the capping layer 915 on other layers and/or structures exposed through the openings in the pattern 910 in the hard mask layer 905 such as the dielectric layer 610 and/or the active region isolation structure(s) 705.

To achieve the selective deposition of the material of the capping layer 915 on the gate structures 805, a precursor of the material of the capping layer 915 and a reactant may be selected to achieve a reaction on the metal material of the gate structures 805 so that the precursor and the reactant react to deposit the material of the capping layer 915 only on the metal material of the gate structures 805. Additionally and/or alternatively, a surface treatment operation may first be performed on the exposed surfaces of the gate structures 805 with a surface modifier (e.g., a self-assembled monolayer) that promotes adhesion of the material of the capping layer 915. Additionally and/or alternatively, a surface treatment operation may first be performed on the exposed surfaces of the dielectric layer 610 with a surface modifier (e.g., a chemical agent) that inhibits adhering of the material of the capping layer 915 to the surfaces of the dielectric layer 610.

In some implementations, the material of the capping layer 915 is non-selectively deposited over the semiconductor device 105, and an etch-back operation is performed to remove portions of the material of the capping layer 915 so that the capping layer 915 remains only on the gate structures 805. For example, a deposition tool may be used to blanket deposit the material of the capping layer 915, and a pattern in a photoresist layer is used to etch the material of the capping layer 915 to remove the material of the capping layer 915 that is not on the gate structures 805.

In some implementations, a combination of selective deposition and etching is used to define the capping layer 915. For example, the selective deposition techniques described above may be performed to deposit the material of the capping layer 915, and a subsequent etch-back operation may be performed to remove material of the capping layer 915 from areas of the semiconductor device 105 other than the gate structures 805. Because of the use of the selective deposition techniques, a lesser amount of material of the capping layer 915 may be deposited on areas of the semiconductor device 105 other than the gate structures 805. Thus, the z-direction thickness of the capping layer 915 on the gate structures 805 may be greater than the z-direction thickness of the capping layer 915 on other areas of the semiconductor device 105. This enables a mask-free etch to be performed to remove the material of the capping layer 915 that was deposited on areas of the semiconductor device 105 other than the gate structures 805. In particular, the greater z-direction thickness of the capping layer 915 on the gate structures 805 enables the material of the capping layer 915 on other areas of the semiconductor device 105 to be fully removed before the capping layer 915 on the gate structures 805 is fully consumed.

As shown in FIG. 9C, cut source/drain recesses 920 are formed based on the pattern 910 in the hard mask layer 905. The cut source/drain recesses 920 may be referred to as cut source/drain recesses in that a cut source/drain recess 920 extends in the x-direction between source/drain regions 510 that are laterally adjacent in the y-direction, and portions of the sides of those source/drain regions 510 are removed (or “cut”) in the process of forming the cut source/drain recess 920.

To form the cut source/drain recesses 920, an etch tool may be used to perform one or more etch operations to etch through the sides of two or more that are laterally adjacent source/drain regions 510 in the x-direction. The etch operation(s) may include vertical etching (or primarily vertical etching) from the top of the semiconductor device 105 through the dielectric layer 610, through the capping layer 515 on the sides of the source/drain regions 510 in the y-direction, through the sides of the source/drain regions 510 in the y-direction, and through the dielectric layer 605 that is laterally adjacent source/drain regions 510 in the y-direction. In some implementations, the etch operation(s) may include vertical etching (or primarily vertical etching) into the STI regions 170 under the dielectric layer 605. In this way, a cut source/drain recess 920 may extend from the hard mask layer 905 through the hard mask layer 905, through a capping layer 515 on sides of source/drain regions 510 that are laterally adjacent in the y-direction, through the sides of the source/drain regions 510, through the dielectric layer 605 that is between the source/drain regions 510 in the y-direction, and into an STI region 170 under the dielectric layer 605.

In some implementations, the cut source/drain recesses 920 may be formed by plasma-based etching and/or another type of anisotropic etching. This enables a high aspect ratio (e.g., a ratio of the depth of a cut source/drain recess 920 in the z-direction to a lateral width of the cut source/drain recess 920 in the y-direction) to be achieved for the cut source/drain recesses 920.

Additionally and/or alternatively, another etch technique may be used to form the cut source/drain recesses 920. The capping layer 915 on the gate structures 805 protects the gate structures 805 from being etched during the formation of the cut source/drain recesses 920.

In some implementations, a source/drain region 510 may have flat sidewalls (e.g., vertical flat sidewalls) in the y-direction where cut source/drain recesses 920 are formed on opposing sides of the source/drain region 510 in the y-direction. In some implementations, a source/drain region 510 may have asymmetric sidewalls in the y-direction, such as a flat vertical sidewall and a curved opposing sidewall in the y-direction where a cut source/drain recess 920 is formed on only one side of the source/drain region 510 in the y-direction.

A source/drain region 510 that has at least one cut sidewall may have a width or diameter in the y-direction that is less than a width or diameter for another source/drain region 510 that does not have at least one cut sidewall. A source/drain region 510 that has sidewalls in the y-direction that are both cut may have a width or diameter in the y-direction that is less than a width or diameter for another source/drain region 510 that has only one sidewall that is cut in the y-direction.

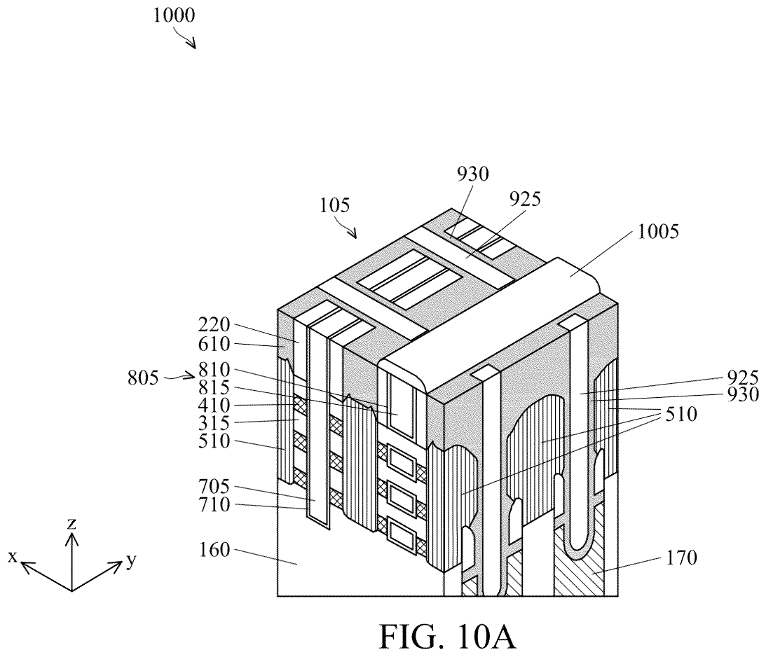

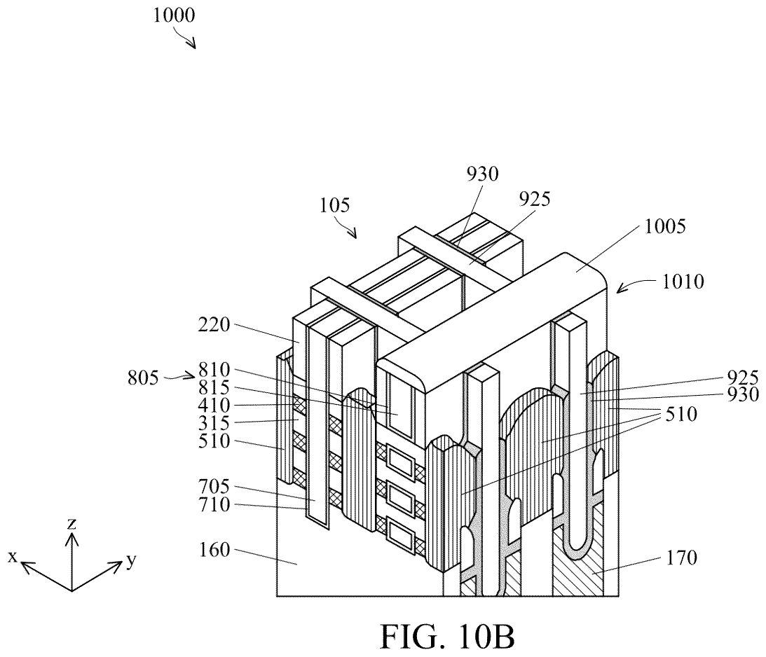

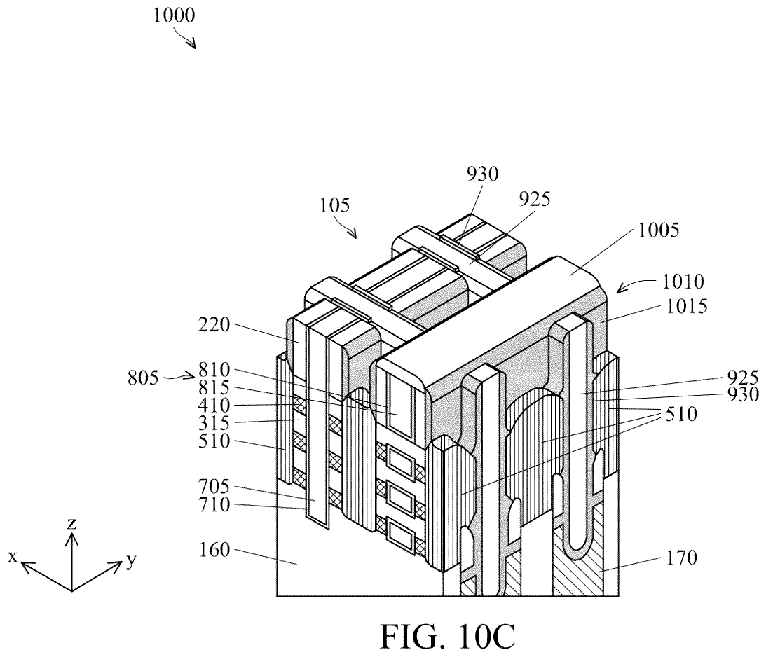

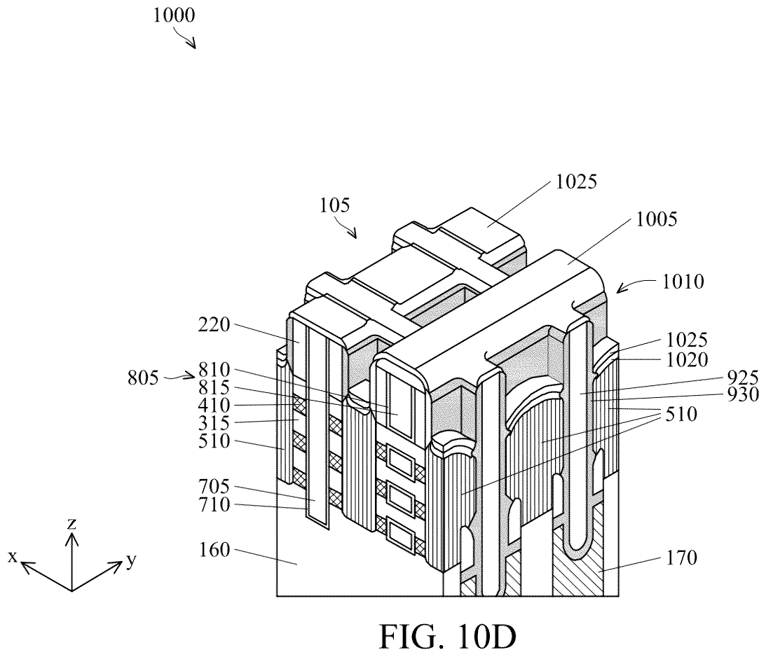

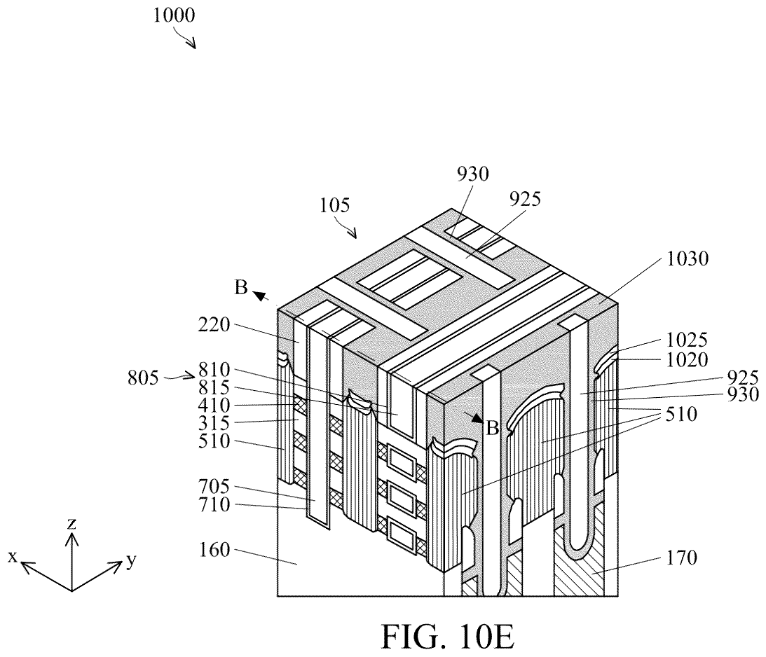

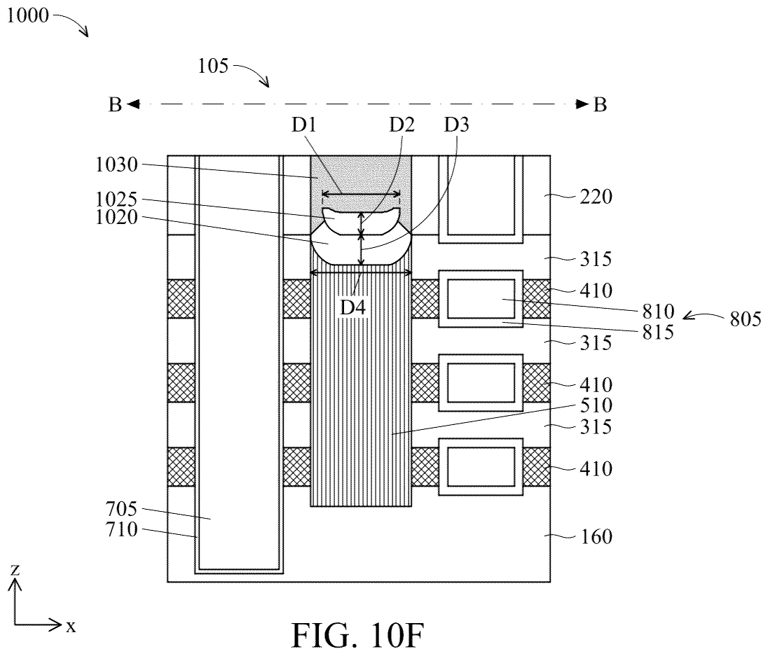

As shown in FIG. 9D, the cut source/drain recesses 920 may be filled in to form source/drain isolation structures 925 in the cut source/drain recesses 920. The source/drain isolation structures 925 may extend in the z-direction and in the x-direction in the semiconductor device 105. In some implementations, a source/drain isolation structure 925 extends through one or more active region isolation structures 705 in the x-direction. A source/drain isolation structure 925 may be located laterally between source/drain regions 510 that are laterally adjacent in the y-direction and may provide electrical isolation between the source/drain regions 510. Moreover, the source/drain isolation structures 925 located laterally adjacent to opposing sides of a source/drain region 510 in the y-direction provides a defined barrier for forming a metal silicide layer fully across the surface of the source/drain region 510 in the y-direction in a subsequent salicidation process described in connection with FIGS. 10A-10F.

In some implementations, a source/drain isolation structure 925 extends lower into the semiconductor device in the z-direction than an active region isolation structure 705. In other words, the bottom surface of the source/drain isolation structure 925 may be located at a lower vertical (z-direction) position in the semiconductor device 105 than the bottom surface of the active region isolation structure 705.

In some implementations, an active region isolation structure 705 extends lower into the semiconductor device in the z-direction than a source/drain isolation structure 925. In other words, the bottom surface of the active region isolation structure 705 may be located at a lower vertical (z-direction) position in the semiconductor device 105 than the bottom surface of the source/drain isolation structure 925.

In some implementations, the bottom surfaces of an active region isolation structure 705 and a source/drain isolation structure 925 are approximately co-planar in an x-y plane in the semiconductor device 105.

In some implementations, a source/drain isolation structure 925 extends into one or more underlying STI regions 170. In some implementations, a source/drain isolation structure 925 has substantially vertical and non-tapered sidewalls. In some implementations, a source/drain isolation structure 925 has tapered sidewalls such that a y-direction width of the source/drain isolation structure 925 decreases from a top of the source/drain isolation structure 925 to a bottom of the source/drain isolation structure 925.

As shown in FIG. 9D, the cut source/drain recesses 920 may be lined with a conformal liner 930, and the material of the source/drain isolation structures 925 may be deposited on the liner 930 in the source/drain isolation structures 925 to fill the cut source/drain recesses 920. The liner 930 may include one or more dielectric materials such as a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. The source/drain isolation structures 925 may each include one or more dielectric materials such as a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material.

In some implementations, the liner 930 and the source/drain isolation structures 925 include different dielectric materials. For example, the liner 930 may include a silicon nitride (SiₓN_{y}) and the source/drain isolation structures 925 may include a silicon oxide (SiOₓ). In some implementations, the liner 930 and the source/drain isolation structures 925 include the same dielectric material.

In some implementations, the active region isolation structures 705 and the source/drain isolation structures 925 include different dielectric materials. For example, the active region isolation structures 705 may include silicon oxycarbide (SiOC) and the source/drain isolation structures 925 may include a silicon oxide (SiOₓ). In some implementations, the active region isolation structures 705 and the source/drain isolation structures 925 include the same dielectric material.

A deposition tool may be used to deposit the material of the liner 930 using a conformal deposition technique such as ALD and/or CVD, among other examples. A deposition tool may be used to deposit the material of the source/drain isolation structures 925 using a deposition technique such as ALD, CVD, PVD, and/or oxidation, among other examples. In some implementations, a planarization tool is used to perform a planarization operation such as a CMP operation to remove excess material from the source/drain isolation structures 925. The dielectric layer 610 may also be removed in the planarization operation. The planarization operation may result in the tops of the source/drain isolation structures 925 being approximately co-planar with the top of the dielectric layer 610.

As indicated above, FIGS. 9A-9D are provided as an example. Other examples may differ from what is described with regard to FIGS. 9A-9D.

FIGS. 10A-10F are diagrams of an example implementation 1000 of a metal silicide layer formation process described herein. FIGS. 10A-10E are illustrated from perspective views of the semiconductor device 105, and FIG. 10F is illustrated from a cross-section view along the line B-B in FIG. 10E. The example implementation 1000 includes an example of using the source/drain isolation structures 925 between adjacent source/drain regions 510 in the y-direction to define openings in which metal silicide layers may be formed on the tops of the source/drain regions 510 such that the metal silicide layers fully span the entirety of the top surfaces of the source/drain regions 510 in and/or along the y-direction (which may be difficult to achieve if the metal silicide layers were otherwise formed in a source/drain contact recess defined during a source/drain contact recess process). In some implementations, the operations described in connection with the example implementation 1000 are performed after the operations described in connection with FIGS. 1A-9D.

As shown in FIG. 10A, a hard mask layer 1005 may be formed over and/or on a gate structure 805 such that the hard mask layer 1005 extends along the gate structure 805 in the y-direction. Alternatively, the hard mask layer 1005 may be omitted. A deposition tool may be used to deposit the material of the hard mask layer 1005 using a CVD technique, an ALD technique, a PVD technique, and/or another suitable deposition technique.

In some implementations, the hard mask layer 1005 may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. In some implementations, the hard mask layer 1005 may include a metal material such as titanium (Ti), tungsten (W), and/or ruthenium (Ru), among other examples. In some implementations, the hard mask layer 1005 may include another material such as tantalum nitride (TaN) and/or titanium nitride (TiN), among other examples.

In some implementations, the hard mask layer 1005 is selectively formed or grown on the tops of the gate structures 805. In other words, the hard mask layer 1005 is selectively formed or grown on the gate structures 805 with little to no growth or deposition of material of the hard mask layer 1005 on other layers and/or structures of the semiconductor device 105, such as the dielectric layer 610, the active region isolation structure(s) 705, and/or the source/drain isolation structures 925.

To achieve the selective deposition of the material of the hard mask layer 1005 on the gate structures 805, a precursor of the material of the hard mask layer 1005 and a reactant may be selected to achieve a reaction on the metal material of the gate structures 805 so that the precursor and the reactant react to deposit the material of the hard mask layer 1005 only on the metal material of the gate structures 805. Additionally and/or alternatively, a surface treatment operation may first be performed on the exposed surfaces of the gate structures 805 with a surface modifier (e.g., a self-assembled monolayer) that promotes adhesion of the material of the hard mask layer 1005. Additionally and/or alternatively, a surface treatment operation may first be performed on the exposed surfaces of the dielectric layer 610 and the source/drain isolation structures 925 with a surface modifier (e.g., a chemical agent) that inhibits adhering of the material of the hard mask layer 1005 to the surfaces of the dielectric layer 610 and the source/drain isolation structures 925.

In some implementations, the material of the hard mask layer 1005 is non-selectively deposited over the semiconductor device 105, and an etch-back operation is performed to remove portions of the material of the hard mask layer 1005 so that the hard mask layer 1005 remains only on the gate structures 805. For example, a deposition tool may be used to blanket deposit the material of the hard mask layer 1005, and a pattern in a photoresist layer is used to etch the material of the hard mask layer 1005 to remove the material of the hard mask layer 1005 that is not on the gate structures 805.

In some implementations, a combination of selective deposition and etching is used to define the hard mask layer 1005. For example, the selective deposition techniques described above may be performed to deposit the material of the hard mask layer 1005, and a subsequent etch-back operation may be performed to remove material of the hard mask layer 1005 from areas of the semiconductor device 105 other than the gate structures 805. Because of the use of the selective deposition techniques, a lesser amount of material of the hard mask layer 1005 may be deposited on areas of the semiconductor device 105 other than the gate structures 805. Thus, the z-direction thickness of the hard mask layer 1005 on the gate structures 805 may be greater than the z-direction thickness of the hard mask layer 1005 on other areas of the semiconductor device 105. This enables a mask-free etch to be performed to remove the material of the hard mask layer 1005 that was deposited on areas of the semiconductor device 105 other than the gate structures 805. In particular, the greater z-direction thickness of the hard mask layer 1005 on the gate structures 805 enables the material of the hard mask layer 1005 on other areas of the semiconductor device 105 to be fully removed before the hard mask layer 1005 on the gate structures 805 is fully consumed.

As shown in FIG. 10B, the dielectric layer 610 and portions of the liner 930 may be removed from the semiconductor device 105 to form recesses 1010 over the source/drain regions 510. In implementations in which the dielectric layer 610 is omitted and the dielectric layer 605 instead is formed over the source/drain regions 510, the dielectric layer 605 may be removed from the semiconductor device 105 to form recesses 1010 over the source/drain regions 510.

The source/drain isolation structures 925 may define the sidewalls of the recesses 1010 in the y-direction. The spacer layers 220 may define the sidewalls of the recesses 1010 in the x-direction. The source/drain isolation structures 925 and the spacer layers 220 may define a recess 1010 such that substantially entirety of a top surface of a source/drain region 510 is exposed through a recess 1010.

In some implementations, an etch tool may be used to perform a wet etch operation using a wet chemical etchant to etch and remove the dielectric layer 610 (and/or the dielectric layer 605) and portions of the liner 930 to form recesses 1010 over the source/drain regions 510. The hard mask layer 1005 protects the tops of the gate structures 805 from being etched during the etch operation to form the recesses 1010. As shown in FIG. 10B, in some implementations, the wet etching may result in the liner 930 being partially etched back and recessed in areas laterally between the spacer layers 220 and the source/drain isolation structures 925.

In some implementations, the dielectric layer 610 and the liner 930 may include the same material, and a wet etchant that has a high etch rate for the material of the dielectric layer 610 and the liner 930 may be used to form the recesses 1010. The wet etchant may selectively remove the material of the dielectric layer 610 and the liner 930 with little to no etching of the spacer layers 220, the active region isolations structures 705, the source/drain isolation structures 925, and/or the hard mask layer 1005, as these structures may be formed of materials different from the material of the dielectric layer 610 and the liner 930. In some implementations, another type of etch technique, such as a gas-based etch technique, may be used to form the recesses 1010.

As shown in FIG. 10C, a spacer layer 1015 may be formed on sidewalls of the spacer layers 220 and on sidewalls of the source/drain isolation structures 925 exposed in the recesses 1010. The material of the spacer layer 1015 may also refill the recessed portions of the liner 930 between the source/drain isolation structures 925 and the spacer layers 220. The spacer layer 1015 may protect the sidewalls of the spacer layers 220 and on sidewalls of the source/drain isolation structures 925 exposed in the recesses 1010 in a subsequent salicidation process to form metal silicide layers on the top surfaces of the source/drain regions 510 exposed in the recesses 1010.

The spacer layer 1015 may include one or more dielectric materials such as a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. A deposition tool may be used to deposit the material of the spacer layer 1015 using a conformal deposition technique such as ALD and/or CVD, among other examples.

As shown in FIG. 10D, metal silicide layers 1020 may be formed over and/or on the top surfaces of the source/drain regions 510. Since the entirety of (or substantially all of) the top surface of a source/drain region 510 is exposed through a recess 1010 (e.g., because of the recess 1010 being defined by the spacer layers 220 and the source/drain isolation structures 925), a metal silicide layer 1020 covers substantially the entirety of the top surface of the source/drain region 510. In particular, the metal silicide layer 1020 may span across the top surface of the source/drain region 510 in the y-direction (e.g., because of the source/drain isolation structures 925 defining the recess 1010 in the y-direction), and may span across the top surface of the source/drain region 510 in the x-direction as well (e.g., because of the spacer layers 220 defining the recesses 1010 in the x-direction).

The metal silicide layers 1020 may each include a metal silicide material, such as titanium silicide (TiSi), zirconium silicide (ZrSi), cobalt silicide (CoSi), ruthenium silicide (RuSi), nickel silicide (NiSi), and/or nickel platinum silicide (NiPtSi), among other examples.

A salicidation process may be performed to selectively form the metal silicide layers 1020 on the exposed top surfaces of the source/drain regions 510. For example, a deposition tool may be used to deposit metal material (e.g., titanium (Ti), zirconium (Zr), cobalt (Co), ruthenium (Ru), nickel (Ni)) onto the exposed top surfaces of the source/drain regions 510. An annealing operation may be performed to cause the metal material to react with the semiconductor material (e.g., silicon (Si), silicon germanium (SiGe)) of the source/drain regions 510 to form the metal silicide material of the metal silicide layers 1020. Unreacted metal material that was deposited on other areas of the semiconductor device 105 may be subsequently removed.

As further shown in FIG. 10D, a metal capping layer 1025 may be formed on the metal silicide layers 1020 over the tops of the source/drain regions 510 in the recesses 1010. The metal capping layer 1025 may cover substantially the entireties of the metal silicide layers 1020.

The metal capping layer 1025 may be formed on the metal silicide layers 1020 as a protective cover for the metal silicide layers 1020. The metal capping layer 1025 prevents the metal silicide layers 1020 from being exposed to atmospheric conditions and subsequent processing chemicals, which might otherwise degrade the film quality of the metal silicide layers 1020. The metal capping layer 1025 may also function as a seed layer for subsequent formation of source/drain contacts on the source/drain regions 510.

The metal capping layer 1025 may include one or more low-resistance metals, such as tungsten (W), cobalt (Co), titanium (Ti), tantalum (Ta), ruthenium (Ru), and/or iridium (Ir), among other examples. In some implementations, the metal material of the metal capping layer 1025 may be different from the metal constituent of the metal silicide layers 1020. For example, the metal silicide layers 1020 may include titanium silicide (TiSi), and the metal capping layers 1025 may include ruthenium (Ru). In some implementations, the metal material of the metal capping layer 1025 and the metal constituent of the metal silicide layers 1020 may be the same metal. For example, the metal silicide layers 1020 may include cobalt silicide (CoSi), and the metal capping layers 1025 may include cobalt (Co).

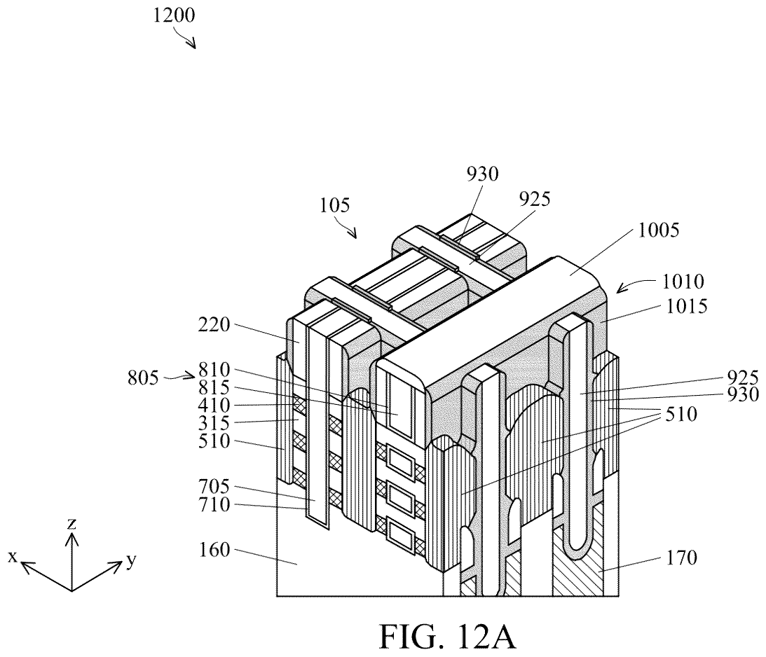

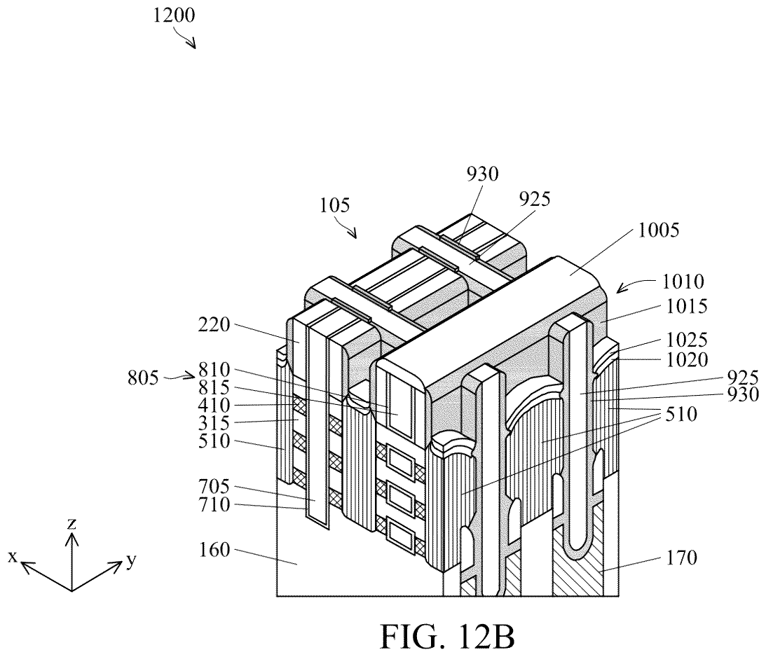

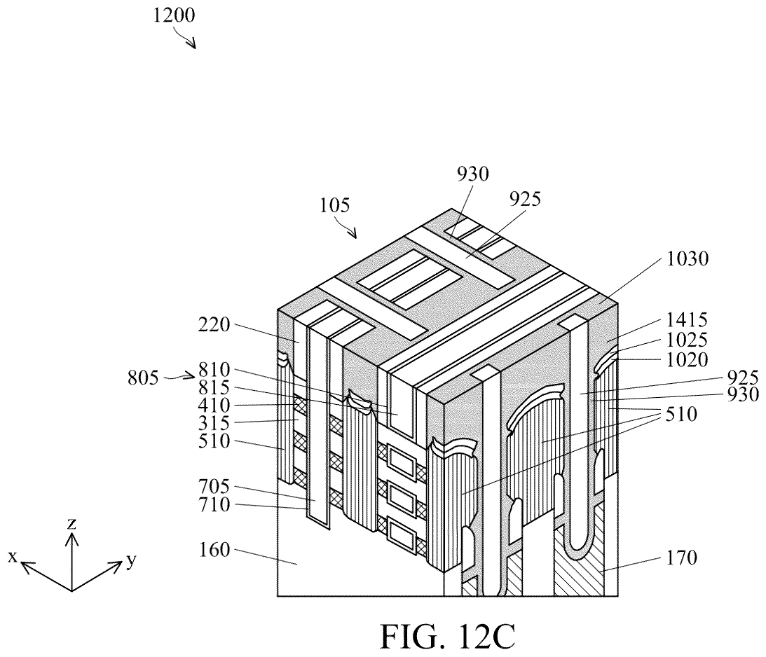

In some implementations, a deposition tool is used to non-selectively deposit the material of the metal capping layer 1025 over the semiconductor device 105, as shown in the example in FIG. 10D. In these implementations, a deposition technique such as PVD, CVD, and/or another suitable deposition technique may be used to deposit the material of the metal capping layer 1025. Material of the metal capping layer 1025 on areas of the semiconductor device 105 other than the metal silicide layers 1020 may be subsequently removed by etching and/or planarization. Alternatively, the material of the metal capping layer 1025 may be selectively deposited only (or primarily) on the metal silicide layers 1020 with little to no deposition of material on other areas of the semiconductor device 105, as illustrated in an example in FIGS. 12A-12C.

As shown in FIG. 10E, the recesses 1010 may be refilled with dielectric material over the metal capping layer 1025 to form a dielectric layer 1030 over the source/drain regions 510. The dielectric layer 1030 may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. In some implementations, the dielectric layer 1030 includes a same dielectric material as the liner 930. In some implementations, the dielectric layer 1030 and the liner 930 include different dielectric materials.

A deposition tool may be used to deposit the dielectric layer 1030 using a PVD technique, an ALD technique, a CVD technique, an oxidation technique, and/or another suitable deposition technique. The dielectric layer 1030 may be deposited in one or more deposition operations. In some implementations, a planarization tool may be used to perform a planarization operation (e.g., a CMP operation) to planarize the dielectric layer 1030 after the dielectric layer 1030 is deposited.

As shown in FIG. 10F, in the x-direction, the top surface of a source/drain region 510 may be recessed and concave due to etching of the top surface of the source/drain region 510 during formation of the recesses 1010. Thus, a metal silicide layer 1020 over and/or on the top surface of the source/drain region 510 may be recessed in the top surface of the source/drain region 510, and may have a similar arc shape or concave profile in the x-direction. Moreover, a metal capping layer 1025 over and/or on the metal silicide layer 1020 may have a similar arc shape or concave profile in the x-direction.

FIG. 10F further illustrates one or more example dimensions of the semiconductor device 105. As shown in FIG. 10F, an example dimension D1 may correspond to a lateral width of a metal capping layer 1025 in the x-direction. In other words, the dimension D1 may correspond to a lateral width of the metal capping layer 1025 between laterally adjacent spacer layers 220 in the x-direction. In some implementations, the dimension D1 is included in a range of approximately 6 nanometers to approximately 20 nanometers so that the metal capping layer 1025 fully covers the underlying metal silicide layer 1020. However, other values and ranges are within the scope of the present disclosure.

Another example dimension D2 may correspond to a z-direction thickness of the metal capping layer 1025. In some implementations, the dimension D2 is included in a range of approximately 2 nanometers to approximately 8 nanometers to provide sufficient protection for the underlying metal silicide layer 1020. However, other values and ranges are within the scope of the present disclosure.

Another example dimension D3 may correspond to a z-direction thickness of the metal silicide layer 1020. In some implementations, the dimension D3 is included in a range of approximately 3 nanometers to approximately 9 nanometers to provide sufficient native oxide formation protection for the underlying source/drain region 510 while achieving a low contact resistance for the source/drain region 510. However, other values and ranges are within the scope of the present disclosure.

Another example dimension D4 may correspond to a lateral width of the metal silicide layer 1020 in the x-direction. In other words, the dimension D4 may correspond to a lateral width of the metal silicide layer 1020 between laterally adjacent spacer layers 220 in the x-direction. The dimension D4 may be greater than the lateral width of a metal capping layer 1025 in the x-direction (e.g., the dimension D2), and may be approximately equal to the lateral length of the source/drain region 510 in the x-direction.

The lateral width of the metal silicide layer 1020 in the x-direction may be greater than the lateral width of a metal capping layer 1025 in the x-direction because of the presence of the spacer layer 1015 on the sidewalls of the recesses 1010 during formation of the metal capping layer 1025. Even though the spacer layer 1015 was on the sidewalls of the recesses 1010 during formation of the metal silicide layer 1020, the metal silicide layer 1020 was formed by salicidation, and therefore a portion of the metal deposited onto the surface of the source/drain region 510 for the salicidation process may diffuse into the surface of the source/drain region 510 under the spacer layer 1015. Thus, the metal silicide layer 1020 may fully extend between the ends of the source/drain region 510 in the x-direction, whereas the metal capping layer 1025 may span less than the entirety of the length of the source/drain region 510 in the x-direction.

As indicated above, FIGS. 10A-10F are provided as an example. Other examples may differ from what is described with regard to FIGS. 10A-10F.

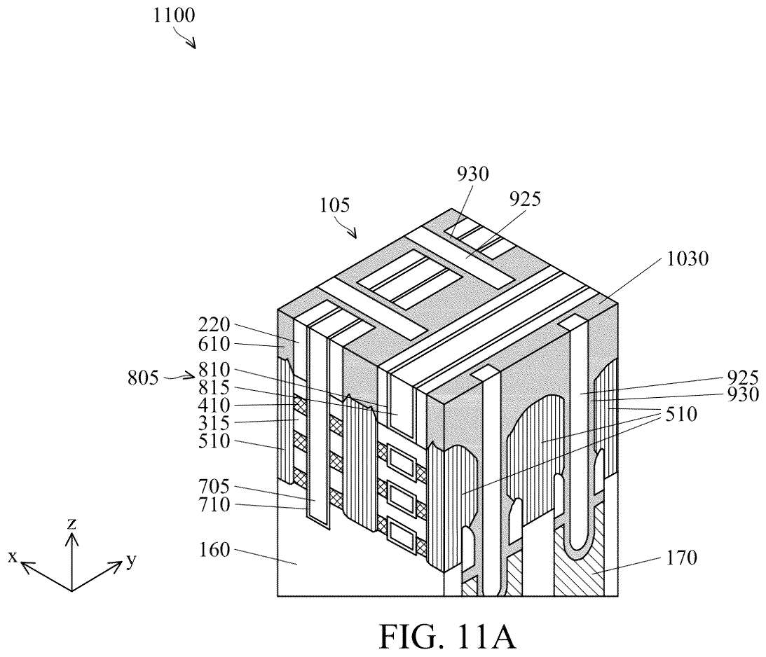

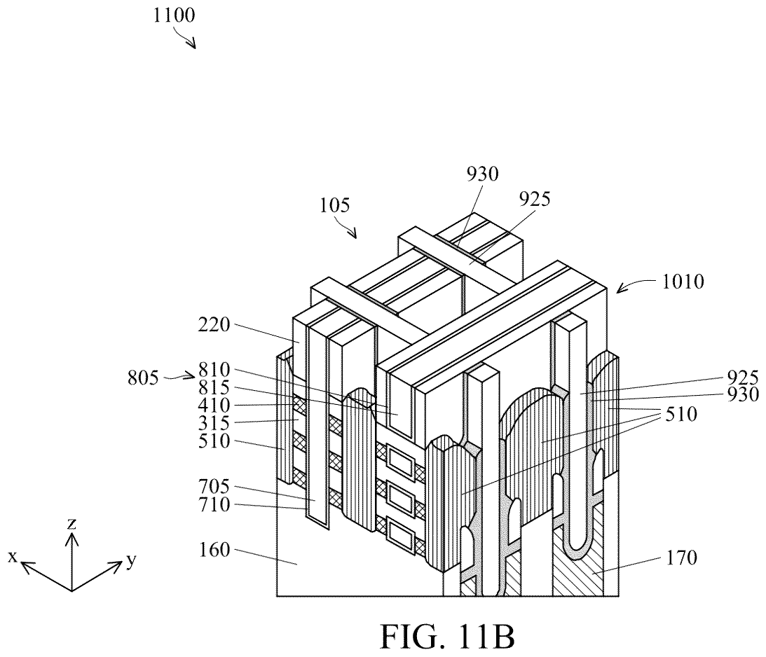

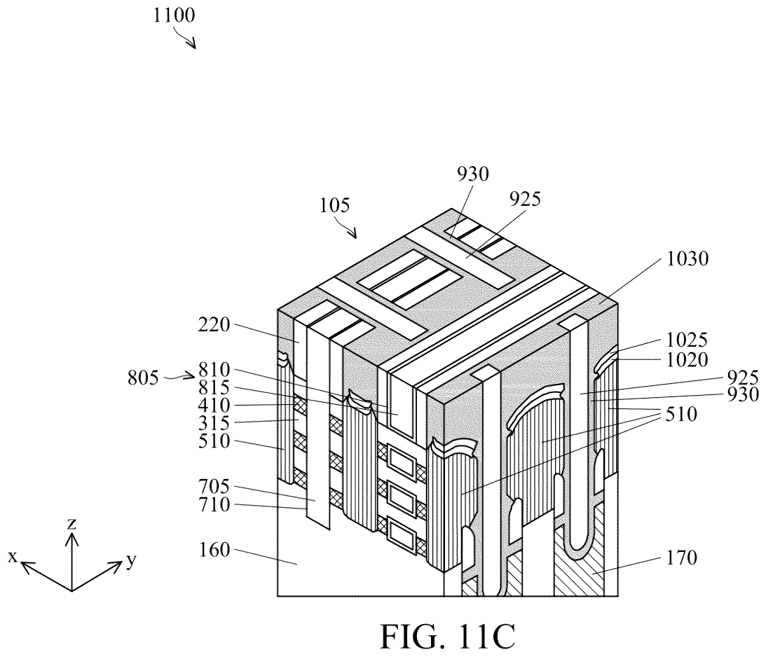

FIGS. 11A-11C are diagrams of an example implementation 1100 of a metal silicide layer formation process described herein. FIGS. 11A-11C are illustrated from perspective views of the semiconductor device 105. The example implementation 1100 is an alternative implementation of the metal silicide layer formation process illustrated and described in connection with FIGS. 10A-10F.

As shown in FIG. 11A, the hard mask layer 1005 may be omitted. As shown in FIG. 11B, the recesses 1010 may be formed without the use of the hard mask layer 1005. An etchant may be used to selectively etch the dielectric layer 610 and the liner 930 with minimal to not etching of the metal material of the gate structures 805. For example, a phosphoric acid etchant, a potassium hydroxide (KOH) etchant, and/or a buffered oxide etchant (BOE) may be used to selectively etch the dielectric layer 610 and the liner 930 with minimal to not etching of the metal material of the gate structures 805.

As shown in FIG. 11C, the metal silicide layers 1020, the metal capping layers 1025, and the dielectric layer 1030 may be formed in a similar manner as described in connection with FIGS. 10A-10F.

As indicated above, FIGS. 11A-11C are provided as an example. Other examples may differ from what is described with regard to FIGS. 11A-11C.

FIGS. 12A-12C are diagrams of an example implementation 1200 of a metal silicide layer formation process described herein. FIGS. 12A-12C are illustrated from perspective views of the semiconductor device 105. The example implementation 1200 is an alternative implementation of the metal silicide layer formation process illustrated and described in connection with FIGS. 10A-10F.

As shown in FIG. 12A, the recesses 1010 may be formed in a similar manner as described in connection with FIGS. 10A-10F. Alternatively, the recesses 1010 may be formed in a similar manner as described in connection with FIGS. 11A-11C.

As shown in FIG. 12B, the metal silicide layers 1020 may be formed, and the metal capping layers 1025 may be formed on the metal silicide layers 1020 in the recesses 1010. In the example implementation 1200, the metal of the metal capping layers 1025 may be selectively deposited by selecting a precursor of the material of the metal capping layers 1025 and a reactant to achieve a reaction on the metal-containing material of the metal silicide layers 1020 so that the precursor and the reactant react to deposit the material of the metal capping layer 1025 only on the metal-containing material of the metal silicide layers 1020. The hard mask layer 1005 on the gate structures 805 prevents the reaction from occurring on the metal material of the gate structures 805.

Additionally and/or alternatively, a surface treatment operation may first be performed on the exposed surfaces of the spacer layers 220, the active region isolation structures 705, the source/drain isolation structures 925, and/or the spacer layer 1015 with a surface modifier (e.g., a self-assembled monolayer) that inhibits adhering of the material of the metal capping layer 1025 to these surfaces.

As shown in FIG. 12C, the dielectric layer 1030 may be formed in a similar manner as described in connection with FIGS. 10A-10F.

As indicated above, FIGS. 12A-12C are provided as an example. Other examples may differ from what is described with regard to FIGS. 12A-12C.

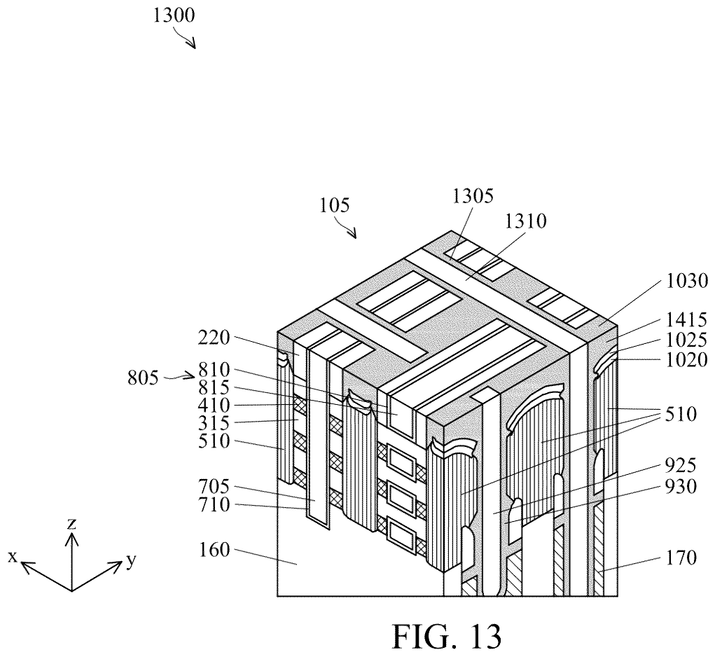

FIG. 13 is a diagram of an example implementation 1300 of a cut metal gate process described herein. FIG. 13 is illustrated from a perspective view of the semiconductor device 105. The example implementation 1300 includes an example of cutting a gate structure 805 into two or more gate structure segments, and forming a gate isolation structure (e.g., a cut metal gate (CMG) structure) between the two or more gate structure segments to electrically isolate the gate structure segments. In some implementations, the operations described in connection with the example implementation 1300 are performed after one or more operations described in connection with FIGS. 1A-12C.

As shown in FIG. 13, a gate isolation structure 1305 may include a dielectric pillar, dielectric column, dielectric wall, and/or another type of electrically insulating structure that is similar to a source/drain isolation structure 925, except that the gate isolation structure 1305 extends through one or more gate structures 805 whereas a source/drain isolation structure 925 does not cut through a gate structure 805. A gate isolation structure 1305 may extend laterally in the x-direction and vertically in the z-direction in the semiconductor device 105. Thus, a gate isolation structure 1305 and a source/drain isolation structure 925 may extend approximately parallel to each other in the semiconductor device 105.

In some implementations, a gate isolation structure 1305 and a source/drain isolation structure 925 are formed in the same process flow illustrated in FIGS. 9A-9D. For example, the capping layer 915 may be omitted from a portion of a gate structure 805 that is exposed through the pattern 910 so that the portion of the gate structure 805 is etched through.

In some implementations, a gate isolation structure 1305 and a source/drain isolation structure 925 are formed in different/separate process flows. For example, a source/drain isolation structure 925 may be formed in a first process flow, and a gate isolation structure 1305 may be formed in a second process flow after the first process flow. As another example, a gate isolation structure 1305 may be formed in a first process flow, and a source/drain isolation structure 925 may be formed in a second process flow after the first process flow. Forming the gate isolation structure 1305 and the source/drain isolation structure 925 in separate process flows enables the gate isolation structure 1305 and the source/drain isolation structure 925 to be formed to have different attributes, such as different depths, different widths, different materials, and/or different shapes, among other examples.

Prior to forming the gate isolation structure 1305, a liner 1310 may be conformally deposited, and the material of the gate isolation structure 1305 may be deposited onto the liner 1310. The liner 1310 may include one or more dielectric materials such as a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. The gate isolation structure 1305 may include one or more dielectric materials such as a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material.

In some implementations, the liner 1310 and the gate isolation structure 1305 include different dielectric materials. For example, the liner 1310 may include a silicon nitride (SiₓN_{y}) and the gate isolation structure 1305 may include a silicon oxide (SiOₓ). In some implementations, the liner 1310 and the gate isolation structure 1305 include the same dielectric material.

In some implementations, the active region isolation structures 705 and the gate isolation structure 1305 include different dielectric materials. For example, the active region isolation structures 705 may include silicon oxycarbide (SiOC) and the gate isolation structure 1305 may include a silicon oxide (SiOₓ). In some implementations, the active region isolation structures 705 and the gate isolation structure 1305 include the same dielectric material.

In some implementations, the source/drain isolation structures 925 and the gate isolation structure 1305 include different dielectric materials. For example, the source/drain isolation structures 925 may include silicon oxycarbide (SiOC) and the gate isolation structure 1305 may include a silicon oxide (SiOₓ). In some implementations, the source/drain isolation structures 925 and the gate isolation structure 1305 include the same dielectric material.

A deposition tool may be used to deposit the material of the liner 1310 using a conformal deposition technique such as ALD and/or CVD, among other examples. A deposition tool may be used to deposit the material of the gate isolation structure 1305 using a deposition technique such as ALD, CVD, PVD, and/or oxidation, among other examples. In some implementations, a planarization tool is used to perform a planarization operation such as a CMP operation to remove excess material from the gate isolation structure 1305.

As indicated above, FIG. 13 is provided as an example. Other examples may differ from what is described with regard to FIG. 13.

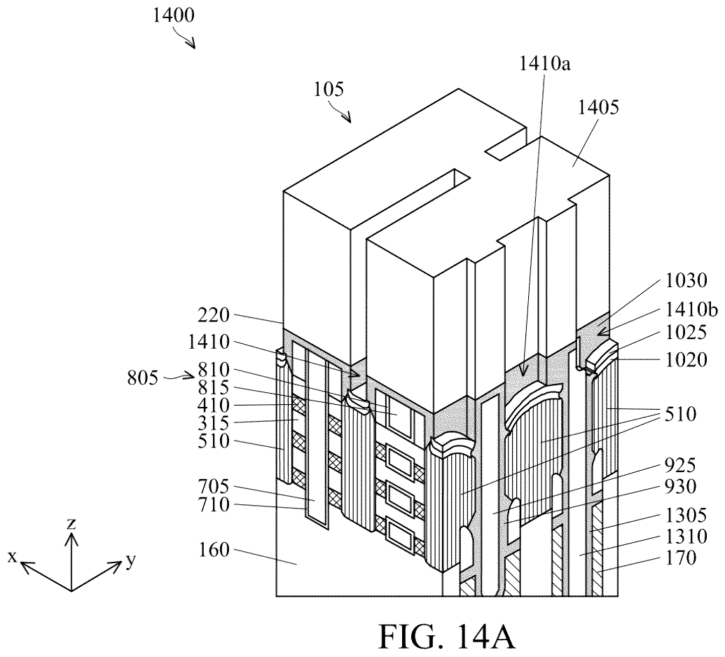

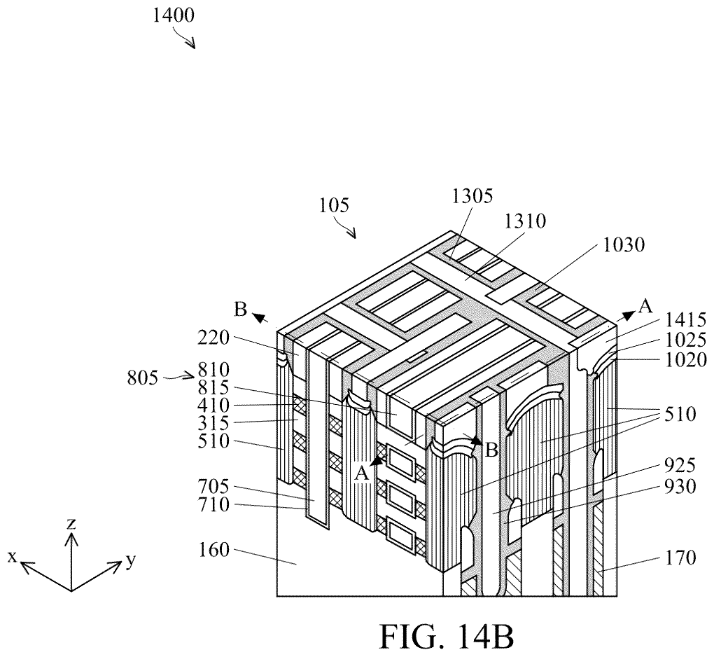

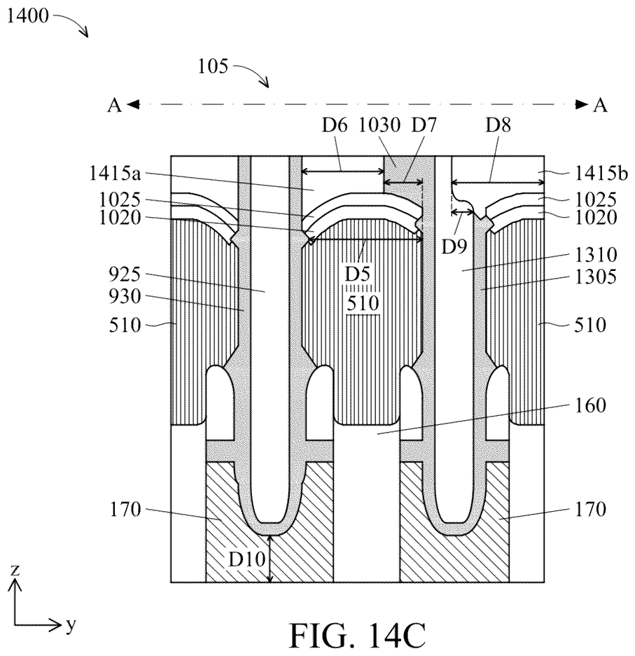

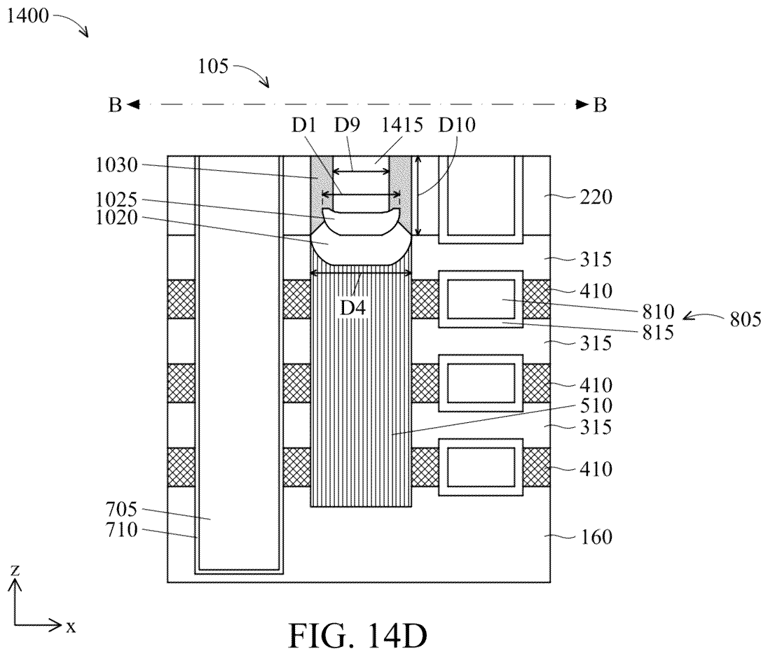

FIGS. 14A-14D are diagrams of an example implementation 1400 of a source/drain contact formation process described herein. FIGS. 14A and 14B are illustrated from perspective views of the semiconductor device 105, FIG. 14C is illustrated from a cross-section view along the line A-A in FIG. 14B, and FIG. 14D is illustrated from a cross-section view along the line B-B in FIG. 14B. The example implementation 1400 includes an example of forming source/drain contacts on source/drain regions 510 of the semiconductor device 105. In some implementations, the operations described in connection with the example implementation 1400 are performed after one or more operations described in connection with FIGS. 1A-13.

As shown in FIG. 14A, a hard mask layer 1405 may be formed over the semiconductor device 105. The hard mask layer 1405 may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another suitable dielectric material. A deposition tool may be used to deposit the material of the hard mask layer 1405 using a PVD technique, an ALD technique, a CVD technique, an epitaxy technique, an oxidation technique, and/or another suitable deposition technique. In some implementations, a planarization tool may be used to perform a planarization operation (e.g., a CMP operation) to planarize the hard mask layer 1405 after the hard mask layer 1405 is deposited.

As further shown in FIG. 14A, a pattern may be formed in the hard mask layer 1405. The pattern may include openings through the hard mask layer 1405. The openings may extend in the y-direction. In some implementations, a pattern in a photoresist layer is used to etch the hard mask layer 1405 to form the pattern. In these implementations, a deposition tool may be used to form the photoresist layer on the hard mask layer 1405 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the hard mask layer 1405 based on the pattern to form the pattern. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

As further shown in FIG. 14A, the pattern in the hard mask layer 1405 may be used to etch the dielectric layer 1030 to form source/drain recesses 1410 in the dielectric layer 1030. A source/drain recess 1410 may be formed over a source/drain region 510 such that at least a portion of the metal capping layer 1025 over the top surface of the source/drain region 510 is exposed through the source/drain recess 1410. An etch tool may be used to etch the dielectric layer 1030 based on the pattern in the hard mask layer 1405 to form the source/drain recesses 1410. In some implementations, the etch operation includes a dry etch operation (e.g., a plasma-based etch operation, a gas-based etch operation), a wet chemical etch operation, and/or another type of etch operation.

As further shown in FIG. 14A, some of the source/drain recesses 1410, such as a source/drain recess 1410a, may be formed such that less than an entirety of a metal capping layer 1025 along the y-direction is exposed through the source/drain recess 1410a. A portion of the metal capping layer 1025 may remain covered by the dielectric layer 1030. Some source/drain recesses 1410, such as a source/drain recess 1410b, may be formed such that a portion of the source/drain recess 1410b is etched into a portion of a source/drain isolation structure 925 that is laterally adjacent to a source/drain region 510 at the bottom of the source/drain recess 1410b.

As shown in FIG. 14B, source/drain contacts 1415 may be formed in the source/drain recesses 1410 such that the source/drain contacts 1415 are above and electrically coupled to the source/drain regions 510. The source/drain contacts 1415 may include one or more low-resistance metals, such as tungsten (W), cobalt (Co), titanium (Ti), tantalum (Ta), ruthenium (Ru), and/or iridium (Ir), among other examples. In some implementations, the metal material of the source/drain contacts 1415 may be different from the metal material of the metal capping layer 1025. For example, the source/drain contacts 1415 may include tungsten (W), and the metal capping layers 1025 may include ruthenium (Ru). In some implementations, the metal material of the source/drain contacts 1415 and the metal material of the metal capping layer 1025 may be the same metal material.

A deposition tool may be used to deposit the material of the source/drain contacts 1415 using a CVD technique, a PVD technique, an ALD technique, an electroplating technique, and/or another suitable deposition technique. The material of the source/drain contacts 1415 may be deposited in one or more deposition operations. In some implementations, a seed layer is first deposited, and the material of the source/drain contacts 1415 is deposited on the seed layer. In some implementations, a planarization tool is used to perform a planarization operation (e.g., a CMP operation) to planarize the source/drain contacts 1415 after the source/drain contacts 1415 are deposited. In some implementations, the hard mask layer 1405 may be removed in the planarization operation. In some implementations, the hard mask layer 1405 may be removed prior to formation of the source/drain contacts 1415.

In this way, the metal silicide layers 1020 of the transistor structures of the semiconductor device 105 are formed prior to formation of the source/drain recesses 1410 and prior to formation of the source/drain contacts 1415. The metal silicide layers 1020 are formed in recesses 1010 that were formed prior to the formation of the source/drain recesses 1410 and prior to formation of the source/drain contacts 1415. The use of the recesses 1010 to define the coverage of the metal silicide layers 1020 across the top surfaces of the source/drain regions 510 enables the metal silicide layers 1020 to be formed such that the metal silicide layers 1020 substantially cover the entireties of the top surfaces of the source/drain regions 510, which may not be possible to achieve if the metal silicide layers 1020 were formed in the source/drain recesses 1410, such as where a source/drain recess 1410a does not fully expose the entire surface of an underlying source/drain region 510.

The full coverage of the metal silicide layers 1020 on the source/drain regions 510 provides for more a flexible layout of the source/drain contacts 1415 and the gate structures 805. For example, adjacent source/drain contacts 1415 may be laterally shifted in the y-direction and/or the lateral size of the source/drain contacts 1415 in the y-direction may be selected to achieve a high density of source/drain contacts 1415 and/or to achieve minimum spacing distances for electrical isolation, and the full coverage of the metal silicide layers 1020 on the source/drain regions 510 facilitates this flexible layout of source/drain contacts 1415. As another example, a source/drain contacts 1415 may be laterally shifted in the x-direction and/or the lateral size of the source/drain contact 1415 in the x-direction may be selected to achieve a minimum spacing distance between the source/drain contact 1415 and an adjacent gate structure 805 for electrical isolation, and the full coverage of the metal silicide layers 1020 on the source/drain regions 510 facilitates this flexible layout of the source/drain contact 1415.

As shown in FIG. 14C, a source/drain contact 1415a (e.g., that was formed in the source/drain recess 1410a) may span less than an entirety of a width of an underlying source/drain region 510 (and less than an entirety of a width of an underlying metal silicide layer 1020 and an underlying metal capping layer 1025) in the y-direction. This is because a portion of the dielectric layer 1030 remains over the source/drain region 510 (and over portions of the underlying metal silicide layer 1020 and the underlying metal capping layer 1025). Thus, a lateral width of the top surface of the source/drain region 510 in the y-direction (dimension D5 in FIG. 14C) may be greater than a lateral width of the source/drain contact 1415a in the y-direction (dimension D6 in FIG. 14C). The lateral width of the top surface of the source/drain region 510 in the y-direction (e.g., the dimension D5) correspond to a combination of the lateral width of the source/drain contact 1415a in the y-direction (e.g., the dimension D6) and a lateral width of the portion of the dielectric layer 1030 over the source/drain region 510 (dimension D7 in FIG. 14C) in the y-direction.

As further shown in FIG. 14C, a source/drain contact 1415b (e.g., that was formed in the source/drain recess 1410b) may have a lateral width in the y-direction (dimension D8 in FIG. 14C) such that a portion of the source/drain contact 1415b extends laterally outward from an underlying source/drain region 510 and over a portion of an adjacent source/drain isolation structure 925 by a distance (dimension D9 in FIG. 14C).

As shown in FIG. 14D, a lateral width of a source/drain contact 1415 in the x-direction (dimension D9 in FIG. 14D) may be less than the lateral width of the underlying metal silicide layer 1020 in the x-direction (dimension D4) and less than the lateral width of the underlying metal capping layer 1025 in the x-direction (dimension D1). In some implementations, a difference between the lateral width of the underlying metal capping layer 1025 in the x-direction (dimension D1) and the lateral width of the source/drain contact 1415 in the x-direction (dimension D9) may be included in a range of approximately 0 nanometers to approximately 6 nanometers. However, other values and ranges are within the scope of the present disclosure. In some implementations, the source/drain contact 1415 may be approximately centered relative to a center of the source/drain region 510 in the x-direction. Alternatively, some overlay shift may occur during formation of the source/drain recess 1410 for the source/drain contact 1415, and the source/drain contact 1415 may be laterally offset in the x-direction relative to the center of the source/drain region 510 in the x-direction.

As further shown in FIG. 14D, the source/drain contact 1415 may have a vertical (z-direction) height (dimension D10 in FIG. 14D) that is included in a range of approximately 5 nanometers to approximately 25 nanometers. However, other values and ranges are within the scope of the present disclosure.

As indicated above, FIGS. 14A-14D are provided as an example. Other examples may differ from what is described with regard to FIGS. 14A-14D.

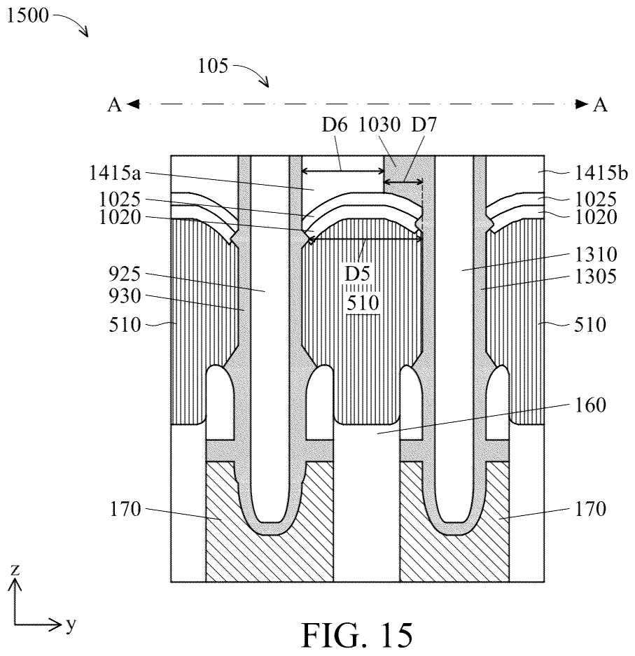

FIG. 15 is a diagram of an example implementation 1500 of the semiconductor device 105 described herein. FIG. 15 is illustrated from a cross-section view along the line A-A in FIG. 14B. FIG. 15 illustrates an alternative x-direction cross-section to the x-direction cross-section illustrated in FIG. 14C. For example, in the example implementation 1500, the source/drain contact 1415a (e.g., that was formed in the source/drain recess 1410a) may span less than an entirety of a width of an underlying source/drain region 510 (and less than an entirety of a width of an underlying metal silicide layer 1020 and an underlying metal capping layer 1025) in the y-direction. However, the source/drain contact 1415b (e.g., that was formed in the source/drain recess 1410b) laterally adjacent to the source/drain contact 1415a in the y-direction terminates at the sidewall of the adjacent source/drain isolation structure 925. In other words, the source/drain contact 1415b does not extend into a portion of the source/drain isolation structure 925 as in the example implementation 1400 illustrated in FIG. 14C.

As indicated above, FIG. 15 is provided as an example. Other examples may differ from what is described with regard to FIG. 15.

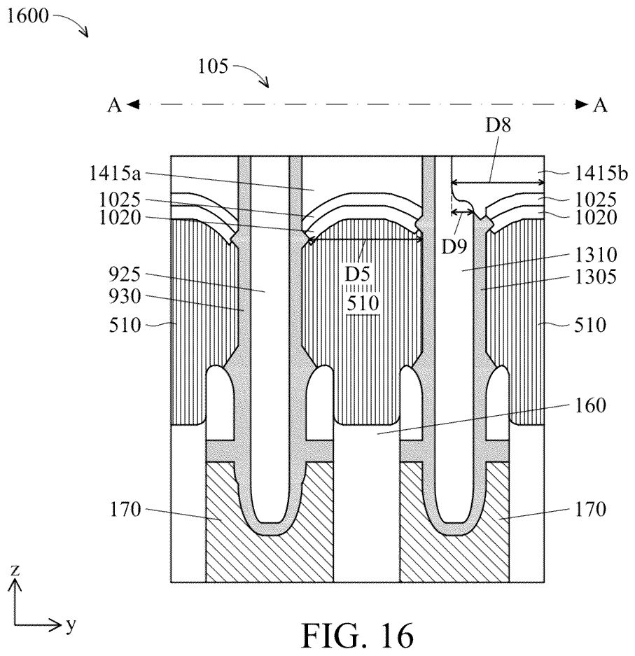

FIG. 16 is a diagram of an example implementation 1600 of the semiconductor device 105 described herein. FIG. 16 illustrates an alternative x-direction cross-section to the x-direction cross-section illustrated in FIG. 14C. For example, in the example implementation 1600, the source/drain contact 1415b (e.g., that was formed in the source/drain recess 1410b) laterally adjacent to the source/drain contact 1415a in the y-direction extends into a portion of the source/drain isolation structure 925. However, the source/drain contact 1415a (e.g., that was formed in the source/drain recess 1410a) may span substantially the entirety of the width of the underlying source/drain region 510 in the y-direction.

As indicated above, FIG. 16 is provided as an example. Other examples may differ from what is described with regard to FIG. 16.

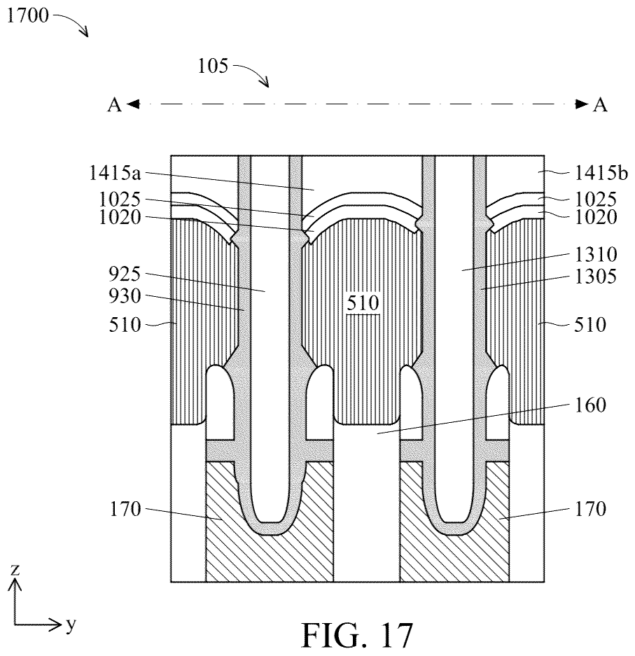

FIG. 17 is a diagram of an example implementation 1700 of the semiconductor device 105 described herein. FIG. 17 is illustrated from a cross-section view along the line A-A in FIG. 14B. FIG. 17 illustrates an alternative x-direction cross-section to the x-direction cross-section illustrated in FIG. 14C. For example, in the example implementation 1700, the source/drain contact 1415a (e.g., that was formed in the source/drain recess 1410a) may span substantially the entirety of the width of the underlying source/drain region 510 in the y-direction, and the source/drain contact 1415b (e.g., that was formed in the source/drain recess 1410b) may also span substantially the entirety of the width of the underlying source/drain region 510 in the y-direction.

As indicated above, FIG. 17 is provided as an example. Other examples may differ from what is described with regard to FIG. 17.

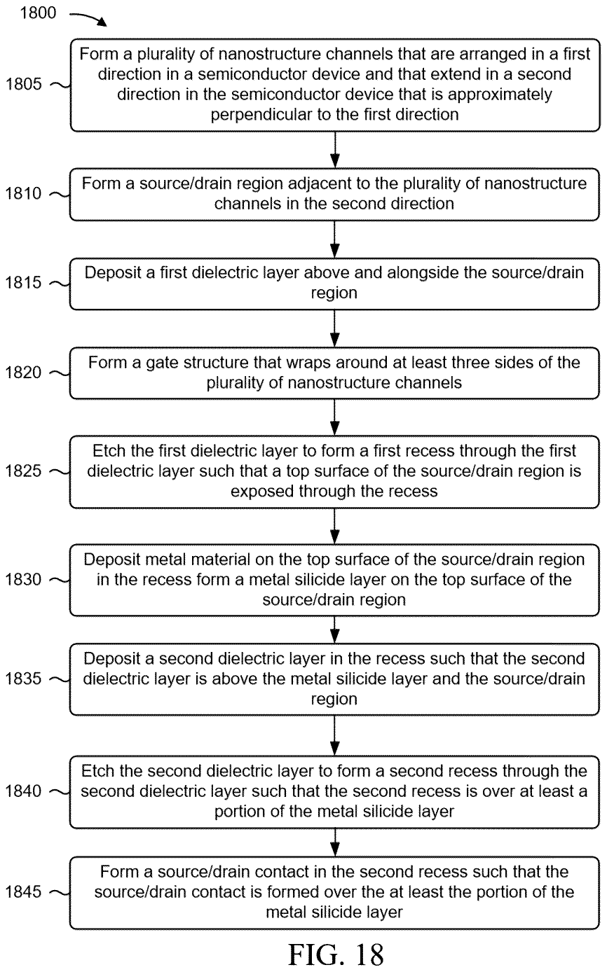

FIG. 18 is a flowchart of an example process 1800 associated with forming a semiconductor device described herein. In some implementations, one or more process blocks of FIG. 18 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 18, process 1800 may include forming a plurality of nanostructure channels that are arranged in a first direction in a semiconductor device 105 and that extend in a second direction in the semiconductor device that is approximately perpendicular to the first direction (block 1805). For example, one or more semiconductor processing tools may be used to form a plurality of nanostructure channels (e.g., nanostructure channels 315) that are arranged in a first direction (e.g., a z-direction) in a semiconductor device (e.g., a semiconductor device 105) and that extend in a second direction (e.g., an x-direction) in the semiconductor device that is approximately perpendicular to the first direction, as described herein.

As further shown in FIG. 18, process 1800 may include forming a source/drain region adjacent to the plurality of nanostructure channels in the second direction (block 1810). For example, one or more semiconductor processing tools may be used to form a source/drain region (e.g., a source/drain region 510) adjacent to the plurality of nanostructure channels in the second direction, as described herein.

As further shown in FIG. 18, process 1800 may include depositing a first dielectric layer above and alongside the source/drain region (block 1815). For example, one or more semiconductor processing tools may be used to deposit a first dielectric layer (e.g., a dielectric layer 605, a dielectric layer 610) above and alongside the source/drain region, as described herein.

As further shown in FIG. 18, process 1800 may include forming a gate structure that wraps around at least three sides of the plurality of nanostructure channels (block 1820). For example, one or more semiconductor processing tools may be used to form a gate structure (e.g., a gate structure 805) that wraps around at least three sides of the plurality of nanostructure channels, as described herein.

As further shown in FIG. 18, process 1800 may include etching the first dielectric layer to form a first recess through the first dielectric layer such that a top surface of the source/drain region is exposed through the recess (block 1825). For example, one or more semiconductor processing tools may be used to etch the first dielectric layer to form a first recess (e.g., a recess 1010) through the first dielectric layer such that a top surface of the source/drain region is exposed through the recess, as described herein.

As further shown in FIG. 18, process 1800 may include depositing metal material on the top surface of the source/drain region in the recess to form a metal silicide layer on the top surface of the source/drain region (block 1830). For example, one or more semiconductor processing tools may be used to deposit metal material on the top surface of the source/drain region in the recess to form a metal silicide layer (e.g., a metal silicide layer 1020) on the top surface of the source/drain region, as described herein.

As further shown in FIG. 18, process 1800 may include depositing a second dielectric layer in the recess such that the second dielectric layer is above the metal silicide layer and the source/drain region (block 1835). For example, one or more semiconductor processing tools may be used to deposit a second dielectric layer (e.g., a dielectric layer 1030) in the recess such that the second dielectric layer is above the metal silicide layer and the source/drain region, as described herein.

As further shown in FIG. 18, process 1800 may include etching the second dielectric layer to form a second recess through the second dielectric layer such that the second recess is over at least a portion of the metal silicide layer (block 1840). For example, one or more semiconductor processing tools may be used to etch the second dielectric layer to form a second recess (e.g., a source/drain recess 1410) through the second dielectric layer such that the second recess is over at least a portion of the metal silicide layer, as described herein.

As further shown in FIG. 18, process 1800 may include forming a source/drain contact in the second recess such that the source/drain contact is formed over the at least the portion of the metal silicide layer (block 1845). For example, one or more semiconductor processing tools may be used to form a source/drain contact (e.g., a source/drain contact 1415, a source/drain contact 1415a, a source/drain contact 1415b) in the second recess such that the source/drain contact is formed over the at least the portion of the metal silicide layer, as described herein.

Process 1800 may include additional implementations, such as any single implementation or any combination of implementations described below and/or in connection with one or more other processes described elsewhere herein.

In a first implementation, forming the second recess includes forming the second recess such that the second recess is over less than an entirety of the metal silicide layer, and forming the source/drain contact in the second recess includes forming the source/drain contact in the second recess such that the source/drain contact is over less than the entirety of the metal silicide layer.

In a second implementation, alone or in combination with the first implementation, process 1800 includes forming a spacer layer (e.g., a spacer layer 1015) on sidewalls of the first recess prior to forming the metal silicide layer.

In a third implementation, alone or in combination with one or more of the first and second implementations, process 1800 includes forming a hard mask layer (e.g., a hard mask layer 1005) on the gate structure prior to forming the first recess.

In a fourth implementation, alone or in combination with one or more of the first through third implementations, forming the first recess includes forming the first recess such that an entire lateral width (e.g., a dimension D4) of the top surface of the source/drain region in the second direction is exposed through the first recess, and forming the metal silicide layer includes forming the metal silicide layer such that the metal silicide layer covers the entire lateral width of the top surface of the source/drain region.

Although FIG. 18 shows example blocks of process 1800, in some implementations, process 1800 includes additional blocks, fewer blocks, different blocks, or differently arranged blocks than those depicted in FIG. 18. Additionally, or alternatively, two or more of the blocks of process 1800 may be performed in parallel.

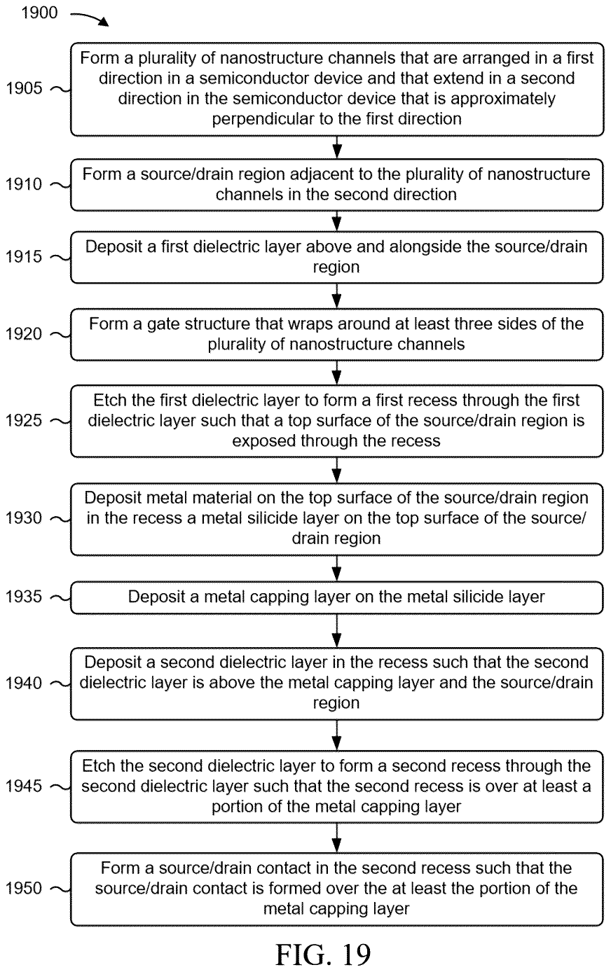

FIG. 19 is a flowchart of an example process 1900 associated with forming a semiconductor device described herein. In some implementations, one or more process blocks of FIG. 19 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 19, process 1900 may include forming a plurality of nanostructure channels that are arranged in a first direction in a semiconductor device and that extend in a second direction in the semiconductor device that is approximately perpendicular to the first direction (block 1905). For example, one or more semiconductor processing tools may be used to form a plurality of nanostructure channels (e.g., nanostructure channels 315) that are arranged in a first direction (e.g., a z-direction) in a semiconductor device (e.g., a semiconductor device 105) and that extend in a second direction (e.g., an x-direction) in the semiconductor device that is approximately perpendicular to the first direction, as described herein.

As further shown in FIG. 19, process 1900 may include forming a source/drain region adjacent to the plurality of nanostructure channels in the second direction (block 1910). For example, one or more semiconductor processing tools may be used to form a source/drain region (e.g., a source/drain region 510) adjacent to the plurality of nanostructure channels in the second direction, as described herein.

As further shown in FIG. 19, process 1900 may include depositing a first dielectric layer above and alongside the source/drain region (block 1915). For example, one or more semiconductor processing tools may be used to deposit a first dielectric layer (e.g., a dielectric layer 605, a hard mask layer 610) above and alongside the source/drain region, as described herein.

As further shown in FIG. 19, process 1900 may include forming a gate structure that wraps around at least three sides of the plurality of nanostructure channels (block 1920). For example, one or more semiconductor processing tools may be used to form a gate structure (e.g., a gate structure 805) that wraps around at least three sides of the plurality of nanostructure channels, as described herein.

As further shown in FIG. 19, process 1900 may include etching the first dielectric layer to form a first recess through the first dielectric layer such that a top surface of the source/drain region is exposed through the recess (block 1925). For example, one or more semiconductor processing tools may be used to etch the first dielectric layer to form a first recess (e.g., a recess 1010) through the first dielectric layer such that a top surface of the source/drain region is exposed through the recess, as described herein.

As further shown in FIG. 19, process 1900 may include depositing metal material on the top surface of the source/drain region in the recess to form a metal silicide layer on the top surface of the source/drain region (block 1930). For example, one or more semiconductor processing tools may be used to deposit metal material on the top surface of the source/drain region in the recess to form a metal silicide layer (e.g., a metal silicide layer 1020) on the top surface of the source/drain region, as described herein.

As further shown in FIG. 19, process 1900 may include depositing a metal capping layer on the metal silicide layer (block 1935). For example, one or more semiconductor processing tools may be used to deposit a metal capping layer (e.g., a metal capping layer 1025) on the metal silicide layer, as described herein.

As further shown in FIG. 19, process 1900 may include depositing a second dielectric layer in the recess such that the second dielectric layer is above the metal capping layer and the source/drain region (block 1940). For example, one or more semiconductor processing tools may be used to deposit a second dielectric layer (e.g., a dielectric layer 1030) in the recess such that the second dielectric layer is above the metal capping layer and the source/drain region, as described herein.

As further shown in FIG. 19, process 1900 may include etching the second dielectric layer to form a second recess through the second dielectric layer such that the second recess is over at least a portion of the metal capping layer (block 1945). For example, one or more semiconductor processing tools may be used to etch the second dielectric layer to form a second recess (e.g., a source/drain recess 1410) through the second dielectric layer such that the second recess is over at least a portion of the metal capping layer, as described herein.

As further shown in FIG. 19, process 1900 may include forming a source/drain contact in the second recess such that the source/drain contact is formed over the at least the portion of the metal capping layer (block 1950). For example, one or more semiconductor processing tools may be used to form a source/drain contact (e.g., a source/drain contact 1415, a source/drain contact 1415a, a source/drain contact 1415b) in the second recess such that the source/drain contact is formed over the at least the portion of the metal capping layer, as described herein.

Process 1900 may include additional implementations, such as any single implementation or any combination of implementations described below and/or in connection with one or more other processes described elsewhere herein.

In a first implementation, depositing the metal capping layer includes depositing the metal capping layer such that the metal capping layer covers an entire lateral width of the top surface of the source/drain region in a third direction that is approximately perpendicular to the first and second directions.

In a second implementation, alone or in combination with the first implementation, depositing the metal capping layer includes forming the metal capping layer of a first metal material, where forming the source/drain contact comprises forming the source/drain contact of a second metal material, and the first metal material and the second metal material are different metal materials.

In a third implementation, alone or in combination with one or more of the first and second implementations, a first lateral width (e.g., a dimension D1) of the metal capping layer in the second direction is greater than a second lateral width (e.g., a dimension D9) of the source/drain contact in the second direction.

In a fourth implementation, alone or in combination with one or more of the first through third implementations, process 1900 includes selectively forming a hard mask layer (e.g., a hard mask layer 1005) on the gate structure prior to forming the first recess, excess material of the metal capping layer is deposited on the hard mask layer, and performing a planarization operation after forming the metal capping layer to remove the hard mask layer and the excess material of the metal capping layer.

In a fifth implementation, alone or in combination with one or more of the first through fourth implementations, depositing the metal capping layer includes depositing metal material of the metal capping layer on the metal silicide layer and on sidewalls of the first recess, and performing an etch operation to remove the metal material of the capping layer from the sidewalls of the first recess.

In a sixth implementation, alone or in combination with one or more of the first through fifth implementations, depositing the metal capping layer includes selectively depositing material of the metal capping layer on the metal silicide layer, wherein a first deposition rate of the material of the metal capping layer on the metal silicide layer is greater than a second deposition rate of the material of the metal capping layer on sidewalls of the first recess.

Although FIG. 19 shows example blocks of process 1900, in some implementations, process 1900 includes additional blocks, fewer blocks, different blocks, or differently arranged blocks than those depicted in FIG. 19. Additionally, or alternatively, two or more of the blocks of process 1900 may be performed in parallel.

In this way, a metal silicide layer is formed on a source/drain region of a transistor (e.g., a nanostructure transistor and/or another type of transistor) of a semiconductor device prior to formation of a recess in which a source/drain contact is to be formed. This enables the coverage of the metal silicide layer on the surface of the source/drain region to be defined independently of the coverage of the source/drain contact (which is defined by the recess in which the source/drain contact is formed).

As described in greater detail above, some implementations described herein provide a method. The method includes forming a plurality of nanostructure channels that are arranged in a first direction in a semiconductor device and that extend in a second direction in the semiconductor device that is approximately perpendicular to the first direction. The method includes forming a source/drain region adjacent to the plurality of nanostructure channels in the second direction. The method includes depositing a first dielectric layer above and alongside the source/drain region. The method includes forming a gate structure that wraps around at least three sides of the plurality of nanostructure channels. The method includes etching the first dielectric layer to form a first recess through the first dielectric layer such that a top surface of the source/drain region is exposed through the recess. The method includes depositing metal material on the top surface of the source/drain region in the recess to form a metal silicide layer on the top surface of the source/drain region. The method includes depositing a second dielectric layer in the recess such that the second dielectric layer is above the metal silicide layer and the source/drain region. The method includes etching the second dielectric layer to form a second recess through the second dielectric layer such that the second recess is over at least a portion of the metal silicide layer. The method includes forming a source/drain contact in the second recess such that the source/drain contact is formed over the at least the portion of the metal silicide layer.

As described in greater detail above, some implementations described herein provide a method. The method includes forming a plurality of nanostructure channels that are arranged in a first direction in a semiconductor device and that extend in a second direction in the semiconductor device that is approximately perpendicular to the first direction. The method includes forming a source/drain region adjacent to the plurality of nanostructure channels in the second direction. The method includes depositing a first dielectric layer above and alongside the source/drain region. The method includes forming a gate structure that wraps around at least three sides of the plurality of nanostructure channels. The method includes etching the first dielectric layer to form a first recess through the first dielectric layer such that a top surface of the source/drain region is exposed through the recess. The method includes depositing metal material on the top surface of the source/drain region in the recess to form a metal silicide layer on the top surface of the source/drain region. The method includes depositing a metal capping layer on the metal silicide layer. The method includes depositing a second dielectric layer in the recess such that the second dielectric layer is above the metal capping layer and the source/drain region. The method includes etching the second dielectric layer to form a second recess through the second dielectric layer such that the second recess is over at least a portion of the metal capping layer. The method includes forming a source/drain contact in the second recess such that the source/drain contact is formed over the at least the portion of the metal capping layer.

As described in greater detail above, some implementations described herein provide a semiconductor device. The semiconductor device includes a plurality of nanostructure channels arranged in a first direction in the semiconductor device. The semiconductor device includes a gate structure wrapping around the plurality of nanostructure channels. The semiconductor device includes a source/drain region adjacent to a side of the gate structure and adjacent to ends of the plurality of nanostructure channels in a second direction that is approximately perpendicular to the first direction. The semiconductor device includes dielectric structures adjacent to opposing sides of the source/drain region in a third direction that is approximately perpendicular to the first and second directions. The semiconductor device includes a metal silicide layer on a top surface of the source/drain region. The semiconductor device includes a source/drain contact above the metal silicide layer, where a first lateral width of the metal silicide layer in the third direction and a second lateral width of the source/drain contact in the third direction are different lateral widths.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure channels that are arranged in a first direction in a semiconductor device and that extend in a second direction in the semiconductor device that is approximately perpendicular to the first direction;
forming a source/drain region adjacent to the plurality of nanostructure channels in the second direction;
depositing a first dielectric layer above and alongside the source/drain region;
forming a gate structure that wraps around at least three sides of the plurality of nanostructure channels;
etching the first dielectric layer to form a first recess through the first dielectric layer such that a top surface of the source/drain region is exposed through the first recess;
depositing metal material on the top surface of the source/drain region in the first recess to form a metal silicide layer on the top surface of the source/drain region;
depositing a second dielectric layer in the first recess such that the second dielectric layer is above the metal silicide layer and the source/drain region;
etching the second dielectric layer to form a second recess through the second dielectric layer such that the second recess is over at least a portion of the metal silicide layer; and
forming a source/drain contact in the second recess such that the source/drain contact is formed over the at least the portion of the metal silicide layer.

2. The method of claim 1, wherein forming the second recess comprises:
forming the second recess such that the second recess is over less than an entirety of the metal silicide layer; and
wherein forming the source/drain contact in the second recess comprises:
forming the source/drain contact in the second recess such that the source/drain contact is over less than the entirety of the metal silicide layer.

3. The method of claim 1, further comprising:
forming a spacer layer on sidewalls of the first recess prior to forming the metal silicide layer.

4. The method of claim 1, further comprising:
forming a hard mask layer on the gate structure prior to forming the first recess.

5. The method of claim 1, wherein forming the first recess comprises:
forming the first recess such that an entire lateral width of the top surface of the source/drain region in the second direction is exposed through the first recess; and
wherein forming the metal silicide layer comprises:
forming the metal silicide layer such that the metal silicide layer covers the entire lateral width of the top surface of the source/drain region.

6. A method, comprising:
forming a plurality of nanostructure channels that are arranged in a first direction in a semiconductor device and that extend in a second direction in the semiconductor device that is approximately perpendicular to the first direction;
forming a source/drain region adjacent to the plurality of nanostructure channels in the second direction;
depositing a first dielectric layer above and alongside the source/drain region;
forming a gate structure that wraps around at least three sides of the plurality of nanostructure channels;
etching the first dielectric layer to form a first recess through the first dielectric layer such that a top surface of the source/drain region is exposed through the first recess;
depositing metal material on the top surface of the source/drain region in the first recess to form a metal silicide layer on the top surface of the source/drain region;
depositing a metal capping layer on the metal silicide layer;
depositing a second dielectric layer in the first recess such that the second dielectric layer is above the metal capping layer and the source/drain region;
etching the second dielectric layer to form a second recess through the second dielectric layer such that the second recess is over at least a portion of the metal capping layer; and
forming a source/drain contact in the second recess such that the source/drain contact is formed over the at least the portion of the metal capping layer.

7. The method of claim 6, wherein depositing the metal capping layer comprises:
depositing the metal capping layer such that the metal capping layer covers an entire lateral width of the top surface of the source/drain region in a third direction that is approximately perpendicular to the first and second directions.

8. The method of claim 6, wherein depositing the metal capping layer comprises:
depositing the metal capping layer of a first metal material;
wherein forming the source/drain contact comprises:
forming the source/drain contact of a second metal material; and
wherein the first metal material and the second metal material are different metal materials.

9. The method of claim 6, wherein a first lateral width of the metal capping layer in the second direction is greater than a second lateral width of the source/drain contact in the second direction.

10. The method of claim 6, further comprising:
selectively forming a hard mask layer on the gate structure prior to forming the first recess,
wherein excess material of the metal capping layer is deposited on the hard mask layer; and
performing a planarization operation after forming the metal capping layer to remove the hard mask layer and the excess material of the metal capping layer.

11. The method of claim 6, wherein depositing the metal capping layer comprises:
depositing metal material of the metal capping layer on the metal silicide layer and on sidewalls of the first recess; and
performing an etch operation to remove the metal material of the capping layer from the sidewalls of the first recess.

12. The method of claim 6, wherein depositing the metal capping layer comprises:
selectively depositing material of the metal capping layer on the metal silicide layer,
wherein a first deposition rate of the material of the metal capping layer on the metal silicide layer is greater than a second deposition rate of the material of the metal capping layer on sidewalls of the first recess.

13. A semiconductor device, comprising:
a plurality of nanostructure channels arranged in a first direction in the semiconductor device;
a gate structure wrapping around the plurality of nanostructure channels;
a source/drain region adjacent to a side of the gate structure and adjacent to ends of the plurality of nanostructure channels in a second direction that is approximately perpendicular to the first direction;
dielectric structures adjacent to opposing sides of the source/drain region in a third direction that is approximately perpendicular to the first and second directions;
a metal silicide layer on a top surface of the source/drain region; and
a source/drain contact above the metal silicide layer,
wherein a first lateral width of the metal silicide layer in the third direction and a second lateral width of the source/drain contact in the third direction are different lateral widths.

14. The semiconductor device of claim 13, wherein the metal silicide layer has an approximate arc shape in the third direction.

15. The semiconductor device of claim 13, wherein the first lateral width of the metal silicide layer in the third direction is less than the second lateral width of the source/drain contact in the third direction.

16. The semiconductor device of claim 13, wherein the first lateral width of the metal silicide layer in the third direction is greater than the second lateral width of the source/drain contact in the third direction.

17. The semiconductor device of claim 13, further comprising:
a metal capping layer on the metal silicide layer,
wherein the source/drain contact is on the metal capping layer.

18. The semiconductor device of claim 17, wherein the source/drain contact comprises a first metal material;
wherein the metal capping layer comprises a second metal material; and
wherein the first metal material and the second metal material are different metal materials.

19. The semiconductor device of claim 13, wherein a bottom surface of a first dielectric structure of the dielectric structures is located at a lower position in the semiconductor device than a bottom surface of a second dielectric structure of the dielectric structures.

20. The semiconductor device of claim 19, wherein the bottom surface of the first dielectric structure and the bottom surface of the second dielectric structure are below a bottom surface of the source/drain region.
